(19) United States
(12) Patent Application Publication
(10) Pub. No.: US 2025/0255152 A1
(43) Pub. Date: Aug. 7, 2025

(54) DISPLAY DEVICE AND ELECTRONIC DEVICE

(71) Applicant: Samsung Display Co., Ltd., Yongin-si (KR)

(72) Inventors: SOODONG KIM, Yongin-si (KR); JUNGHWAN YI, Yongin-si (KR); RAE-YOUNG KIM, Yongin-si (KR); MIN-HEE KIM, Yongin-si (KR); DANBI YANG, Yongin-si (KR); SIMBUM YUK, Yongin-si (KR)

(73) Assignee: Samsung Display Co., Ltd., Yongin-si (KR)

(21) Appl. No.: 19/015,277

(22) Filed: Jan. 9, 2025

(30) Foreign Application Priority Data
Feb. 6, 2024 (KR) 10-2024-0018274

(51) Int. Cl. H10K 59/80; H10K 59/122; H10K 59/38

(52) U.S. Cl. CPC H10K 59/873; H10K 59/122; H10K 59/38

(57) ABSTRACT

A display device includes a base layer, a pixel definition layer on the base layer and including a light emitting opening in the pixel definition layer, a light emitting element overlapping the pixel area and generating a source light, an encapsulation layer including a first inorganic layer covering the light emitting element, an organic layer on the first inorganic layer, and a second inorganic layer on the organic layer, a first dam pattern including a first dam opening in the first dam pattern, a bank on the encapsulation layer, the bank including an opening, a light control pattern in the opening and converting the source light to an output light, a second dam pattern on the bank, the second dam pattern including a second dam opening, and a color filter overlapping the pixel area.

### CROSS-REFERENCE TO RELATED APPLICATION(S)

This application claims priority to and benefits of Korean Patent Application No. 10-2024-0018274 under 35 U.S.C. § 119, filed on Feb. 6, 2024 in the Korean Intellectual Property Office, the entire contents of which are incorporated herein by reference.

### BACKGROUND

### 1. Technical Field

The disclosure relates to a display device. For example, the disclosure relates to a display device including a dam pattern.

### 2. Description of the Related Art

As a display panel, an emissive type display panel that generates a light by itself and emits the light and a transmissive type display panel that transmits a source light generated by a light source after changing optical properties of the source light are widely used. Quantum dots are used to change the optical properties of the source light in the transmissive type display panel.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device with improved color characteristics by preventing a color mixture between pixels, which occurs as the size of pixels decreases with increasing resolution.

Embodiments may include a display device that may include a base layer including a pixel area and a peripheral area surrounding the pixel area; a pixel definition layer disposed on the base layer, the pixel definition layer including a light emitting opening in the pixel definition layer; a light emitting element overlapping the pixel area and generating a source light; an encapsulation layer including a first inorganic layer covering the light emitting element, an organic layer disposed on the first inorganic layer, and a second inorganic layer disposed on the organic layer; a first dam pattern disposed on the pixel definition layer, the first dam pattern including a first dam opening in the first dam pattern, the first dam opening overlapping the peripheral area; a bank disposed on the encapsulation layer, the bank including an opening in the bank; a light control pattern disposed in the opening and converting the source light to an output light; a second dam pattern disposed on the bank, the second dam pattern including a second dam opening in the second dam pattern; and a color filter overlapping the pixel area. The organic layer is disposed in the first dam opening, and the second dam opening is filled with a filling material.

A transmittance of the first dam pattern with respect to the source light may be lower than a transmittance of the encapsulation layer with respect to the source light, and a transmittance of the second dam pattern with respect to the source light may be lower than a transmittance of the filling material with respect to the source light.

A transmittance of the second dam pattern with respect to the output light may be lower than a transmittance of the filling material with respect to the output light.

The display device may further include a first capping layer that covers the bank and the light control pattern.

The first capping layer may contact the light control pattern and has a refractive index equal to or greater than about 1.0 and equal to or less than about 1.5.

The first dam pattern may be disposed on the pixel definition layer and above the light emitting element.

The first dam pattern may be disposed between the first inorganic layer and the organic layer.

The first dam pattern may be disposed between the first inorganic layer and the second inorganic layer, and an upper surface of the first dam pattern may contact the second inorganic layer.

The filling material may have a refractive index equal to or greater than about 1.0 and equal to or less than about 1.5.

The display device may further include a low refractive index layer disposed between the color filter and the filling material.

The display device may further include a reflective pattern disposed on an inner side surface of the first dam pattern.

The display device may further include a block color filter disposed on the color filter. The pixel area may include a first pixel area, a second, pixel area and a third pixel area, the color filter may include a first color filter overlapping the first pixel area and transmitting a first color light, a second color filter overlapping the second pixel area and transmitting a second color light, and a third color filter overlapping the third pixel area and transmitting a third color light, and the block color filter overlaps the first pixel area and the second pixel area and does not overlap the third pixel area.

The block color filter may include an extinction coefficient equal to or greater than about 0.005 and equal to or less than about 0.5 with respect to the third color light.

The block color filter may have a transmittance equal to or greater than about 90% with respect to each of the first color light and the second color light.

Each of the first and second color lights may be a red light or a green light, and the third color light may be a blue light.

Embodiments may include a display device that may include a base layer including a first pixel area, a second pixel area, and a third pixel area and a peripheral area surrounding the first pixel area, the second pixel area, and the third pixel area; a pixel definition layer disposed on the base layer, the pixel definition layer including light emitting openings in the pixel definition layer, a light emitting element overlapping the first pixel area, the second pixel area, and the third pixel area and generating a source light; an encapsulation layer including a first inorganic layer covering the light emitting element, an organic layer disposed on the first inorganic layer, and a second inorganic layer disposed on the organic layer; a first dam pattern disposed on the pixel definition layer, the first dam pattern including (1-1)th, (1-2)th, and (1-3)th dam openings in the first dam pattern, the (1-1)th, (1-2)th, and (1-3)th dam openings overlapping the peripheral area, a bank disposed on the first dam pattern, with the bank including first openings, second openings, and third openings in the bank; a first light control pattern, a second light control pattern, and a third light control pattern disposed in the first openings, the second openings, and the third openings, respectively, and converting an optical property of the source light, and a second dam pattern disposed on the bank, and the second dam pattern including (2-1)th, (2-2)th, and (2-3)th dam openings included in the second dam pattern, respectively. The organic layer is disposed in the (1-1)th, (1-2)th, and (1-3)th dam openings, and the (2-1)th, (2-2)th, and (2-3)th dam openings are filled with a filling material.

The display device may further include a first color filter, a second color filter, and a third color filter disposed on the filling material, respectively overlapping the first pixel area, the second pixel area, and the third pixel area, and respectively transmitting a first color light, a second color light, and a third color light.

The display device may further include a block color filter disposed on the first color filter and the second color filter, and the block color filter overlaps the first pixel area and the second pixel area and does not overlap the third pixel area.

The block color filter may have an extinction coefficient equal to or greater than about 0.005 and equal to or less than about 0.5 with respect to the third color light.

The block color filter may have a transmittance equal to or greater than about 90% with respect to each of the first color light and the second color light.

Embodiments may include electronic device activated in response to electrical signals and including a display device curved with respect to a virtual axis extending in a first direction, an electronic module overlapping the display device and a housing accommodating the display device. The display device may include a base layer including a pixel area and a peripheral area surrounding the pixel area, a pixel definition layer disposed on the base layer, the pixel definition layer including a light emitting opening in the pixel definition layer, a light emitting element overlapping the pixel area and generating a source light, an encapsulation layer including a first inorganic layer covering the light emitting element, an organic layer disposed on the first inorganic layer, and a second inorganic layer disposed on the organic layer, a first dam pattern disposed on the pixel definition layer, the first dam pattern including a first dam opening in the first dam pattern, the first dam opening overlapping the peripheral area, a bank disposed on the encapsulation layer, the bank including an opening in the bank, a light control pattern disposed in the opening and converting the source light to an output light, a second dam pattern disposed on the bank, the second dam pattern including a second dam opening in the second dam pattern, and a color filter overlapping the pixel area. The organic layer is disposed in the first dam opening, and the second dam opening is filled with a filling material.

The electronic device may be television set, computer monitor, outdoor billboard, mobile phone, tablet computer, navigation unit, game unit or smart watch.

The electronic module may include a control module, an image input module and a memory.

According to the above, the display device may include the first dam pattern and the second dam pattern to prevent a color mixture from occurring between pixels in a high-resolution display device, and thus, color characteristics of the display device may be improved.

According to the above, the display device may include an additional color filter that prevents a color mixture between pixels, and thus, color characteristics of the display device may be improved.

### BRIEF DESCRIPTION OF THE DRAWINGS

The above and other advantages of the disclosure will become readily apparent by reference to the following detailed description when considered in conjunction with the accompanying drawings wherein:

FIG. 1 is a schematic perspective view of a display device according to an embodiment;

FIG. 2 is a schematic cross-sectional view of a display device according to an embodiment;

FIG. 3 is a schematic plan view of a display substrate according to an embodiment;

FIG. 4 is an enlarged plan view of a display area according to an embodiment;

FIGS. 5A to 5F are schematic cross-sectional views taken along line I-I′ of FIG. 4;

FIG. 6A is a graph illustrating a wavelength measured in a first pixel area as a function of a spectral intensity according to a comparative example and an embodiment example;

FIG. 6B is a graph illustrating a wavelength measured in a second pixel area as a function of a spectral intensity according to a comparative example and an embodiment example;

FIG. 6C is a graph illustrating a wavelength measured in a third pixel area as a function of a spectral intensity according to a comparative example and an embodiment example;

FIG. 6D is a graph illustrating a light efficiency and a color gamut according to a comparative example and an embodiment example;

FIGS. 7 to 9 are schematic cross-sectional views taken along line I-I′ of FIG. 4 according to an embodiment;

FIG. 10 is a graph illustrating a light transmittance of a block color filter as a function of a wavelength according to an embodiment;

FIG. 11A is a graph illustrating a transmittance of a block color filter with respect to a blue light as a function of a thickness of the block color filter according to an embodiment;

FIG. 11B is a graph illustrating a transmittance of a block color filter as a function of a wavelength in case that a thickness of a block color filter is varied according to an embodiment;

FIG. 12A is a graph illustrating a wavelength measured in a first pixel area as a function of a spectral intensity according to a comparative example and an embodiment example;

FIG. 12B is a graph illustrating a wavelength measured in a second pixel area as a function of a spectral intensity according to a comparative example and an embodiment example;

FIG. 12C is a graph illustrating a light efficiency and a color gamut according to comparative examples and embodiment examples;

FIG. 13 is a perspective view of an electronic device according to an embodiment of the present disclosure;

FIG. 14 is a view illustrating a folded state of the electronic device illustrated in FIG. 13;

FIG. 15 is an exploded perspective view of the electronic device illustrated in FIG. 13;

FIG. 16A is a perspective view of an electronic device according to according to an embodiment of the present disclosure;

FIG. 16B is a perspective view of a curved electronic device according to an embodiment of the present disclosure; and

FIG. 17 is a block diagram of the electronic device illustrated in FIG. 15;

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components may be exaggerated for effective description of the technical content.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure.

As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined, all terms including technical and scientific terms used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described with reference to accompanying drawings.

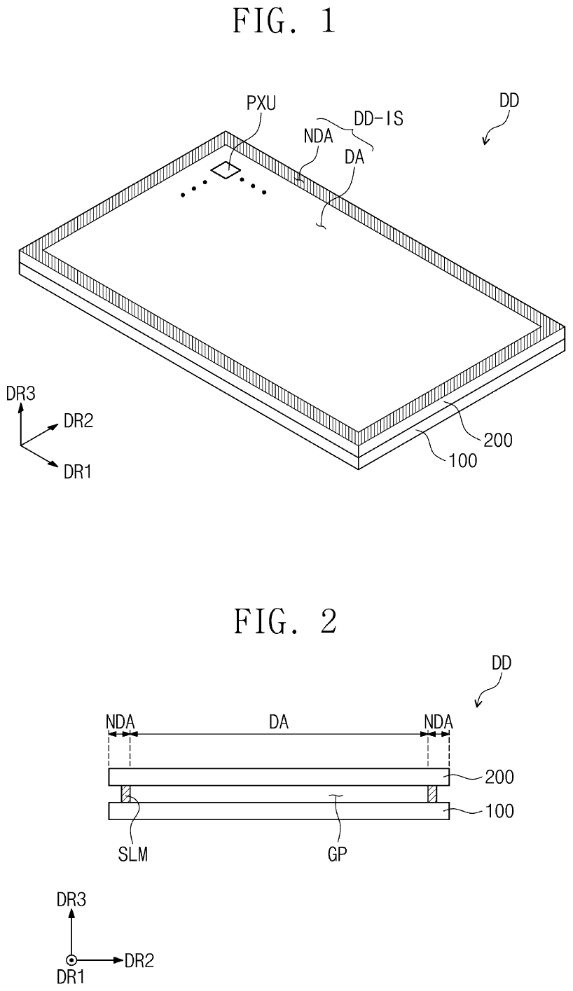

FIG. 1 is a schematic perspective view of a display device DD according to an embodiment. FIG. 2 is a schematic cross-sectional view of the display device DD according to an embodiment.

Referring to FIG. 1, the display device DD may include a display surface DD-IS to display an image through to a front surface thereof. The display device DD may display the image through the display surface DD-IS, which is substantially parallel to a plane defined by a first direction DR1 and a second direction DR2, toward a third direction DR3. The third direction DR3 may intersect each of the first direction DR1 and the second direction DR2, and a normal line direction of the display surface DD-IS may be substantially parallel to the third direction DR3. The image displayed through the display surface DD-IS may include a still image as well as a video.

In the embodiment, front (or upper) and rear (or lower) surfaces of each component of the display device DD may be defined with respect to a direction in which the image is displayed. The front and rear surfaces may be opposite to each other in the third direction DR3. Directions indicated by the first, second, and third directions DR1, DR2, and DR3 are relative to each other, and thus, the directions indicated by the first, second, and third directions DR1, DR2, and DR3 may be changed to other directions.

The display device DD may include a display area DA and a non-display area NDA. Unit pixels PXU may be arranged (or disposed) in the display area DA, and the unit pixels PXU may emit a light in response to electrical signals to display the image through the display area DA. The unit pixels PXU may not be arranged in the non-display area NDA. The non-display area NDA may be defined along an edge of the display surface DD-IS and may surround the display area DA.

The display device DD may be included in an electronic device activated in response to electrical signals. The electronic device may include various embodiments. As an example, the electronic device may be applied to a large-sized electronic item, such as a television set, a computer monitor, an outdoor billboard, etc., and a small and medium-sized electronic item, such as a mobile phone, a tablet computer, a navigation unit, a game unit, smart watch, etc. However, the electronic device according to an embodiment of the inventive concept may not be limited to the above-mentioned examples, and may also be employed in another electronic device as long as it does not deviate from the inventive concept.

The display device DD may be flexible. The term “flexible” used herein refers to the property of being able to be bent from a structure that is completely bent to a structure that is bent at the scale of a few nanometers. For example, the display device DD may be a curved display device or a foldable display device. According to an embodiment, the display device DD may be rigid.

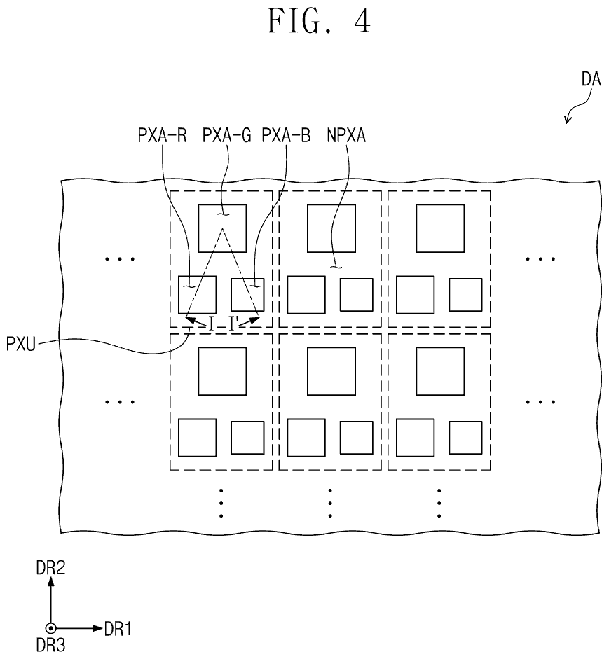

Referring to FIG. 1, the unit pixels PXU may be arranged in rows and columns in the display device DD. The unit pixel PXU may be the smallest repeating unit, and one unit pixel PXU may include at least one pixel area PXA-R, PXA-G, and PXA-B (refer to FIG. 4). According to an embodiment, the one unit pixel PXU may include pixel areas PXA-R, PXA-G, and PXA-B (refer to FIG. 4) that provide lights having different colors from each other.

Referring to FIG. 2, the display device DD may include a first display substrate 100 and a second display substrate 200. The second display substrate 200 may be disposed spaced apart upward from the first display substrate 100.

A cell gap GP may be a space defined between the first display substrate 100 and the second display substrate 200, which are spaced apart from each other. The cell gap GP may be maintained by a sealing member SLM.

The sealing member SLM may be disposed between the first display substrate 100 and the second display substrate 200 and may overlap the non-display area NDA. When viewed in a plane, the sealing member SLM may be aligned with an edge of the second display substrate 200, however, it should not be limited thereto or thereby. The sealing member SLM may hold the second display substrate 200 and the first display substrate 100 so that the second display substrate 200 and the first display substrate 100 are spaced apart from each other by a selectable distance and may prevent external oxygen and moisture from entering the second display substrate 200 and the first display substrate 100.

The sealing member SLM may include a binder resin and inorganic fillers mixed with the binder resin. The sealing member SLM may further include other additives. The additives may include an amine-based curing agent and a photoinitiator. The additives may further include a silane-based additive and an acrylic-based additive. The sealing member SLM may include an inorganic-based material such as a frit.

FIGS. 1 and 2 show the structure in which areas of surfaces of the first display substrate 100 and the second display substrate 200, which face the third direction DR3, are the same as each other, however, the disclosure should not be limited thereto or thereby.

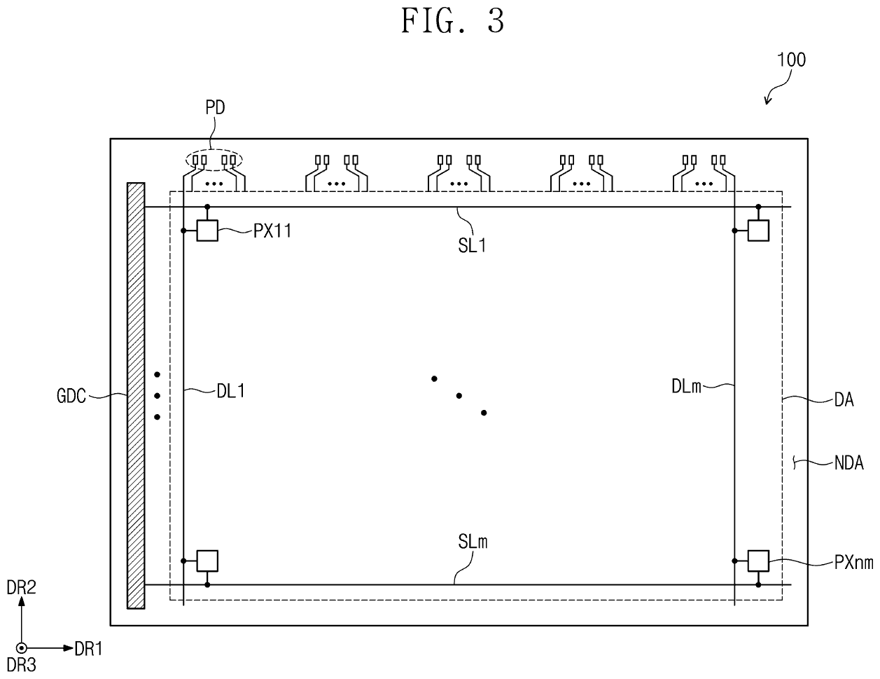

FIG. 3 is a schematic plan view of the first display substrate 100 according to an embodiment, and FIG. 4 is an enlarged plan view of the display area DA according to an embodiment.

Referring to FIG. 3, the first display substrate 100 may include signal lines SLI to SLn and DL1 to DLm and pixels PX11 to PXnm. The signal lines SLI to SLn and DL1 to DLm may include gate lines SLI to SLn and data lines DL1 to DLm. Each of the pixels PX11 to PXnm may be connected to a corresponding gate line of the gate lines SLI to SLn and a corresponding data line of the data lines DL1 to DLm.

Each of the pixels PX11 to PXnm may include a pixel driving circuit and a light emitting element. More types of signal lines may be provided in the first display substrate 100 depending on the configuration of the pixel driving circuit of the pixels PX11 to PXnm.

A gate driving circuit GDC may be integrated in the first display substrate 100 through an oxide silicon gate driver circuit (OSG) process or an amorphous silicon gate driver circuit (ASG) process. The gate driving circuit GDC connected to the gate lines SLI to SLn may be disposed in one side or a side of the non-display area NDA in the first direction DR1. Pads PD connected to ends of the data lines DL1 to DLm may be disposed in one side or a side of the non-display area NDA in the second direction DR2.

FIG. 4 is an enlarged plan view of the display area DA according to an embodiment.

Referring to FIG. 4, the unit pixels PXU may be arranged in the first direction DR1 and the second direction DR2. In the embodiment, the unit pixel PXU may include a first pixel area PXA-R, a second pixel area PXA-G, and a third pixel area PXA-B, which emit lights having different colors from each other. The first pixel area PXA-R, the second pixel area PXA-G, and the third pixel area PXA-B may emit a red light, a green light, and a blue light, respectively.

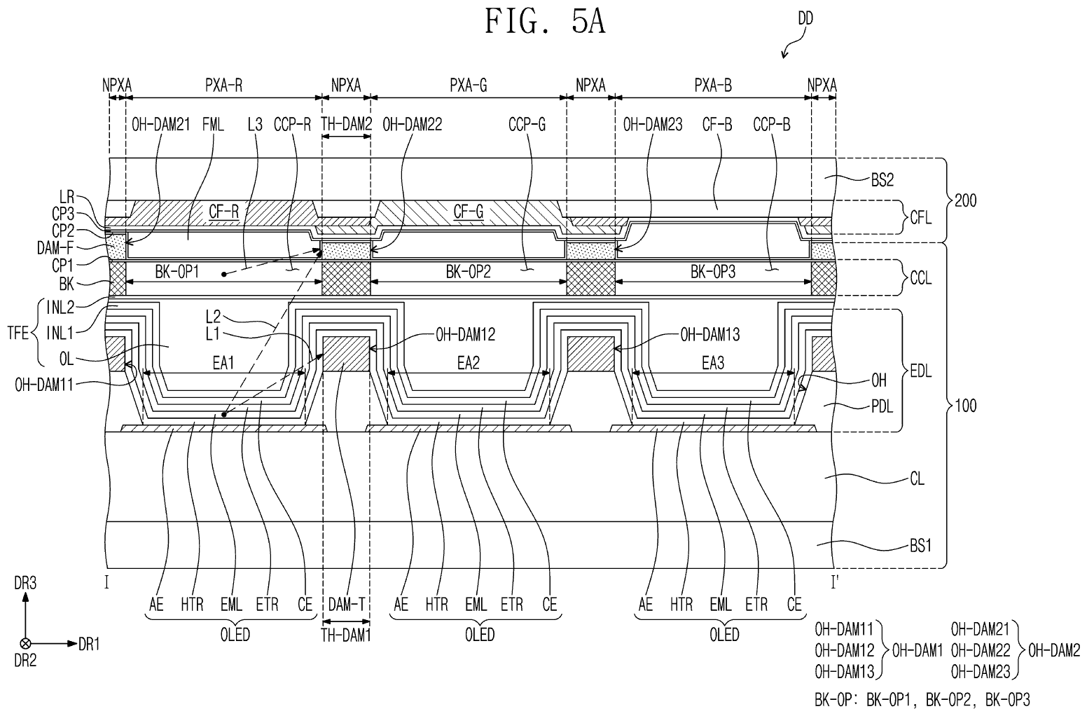

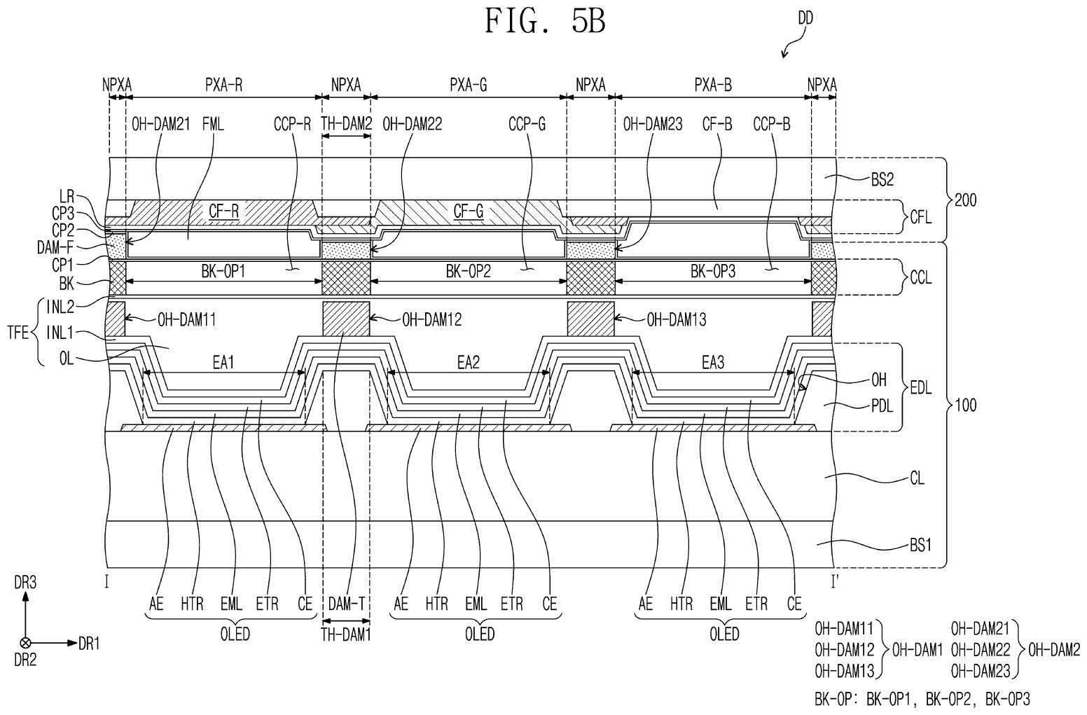

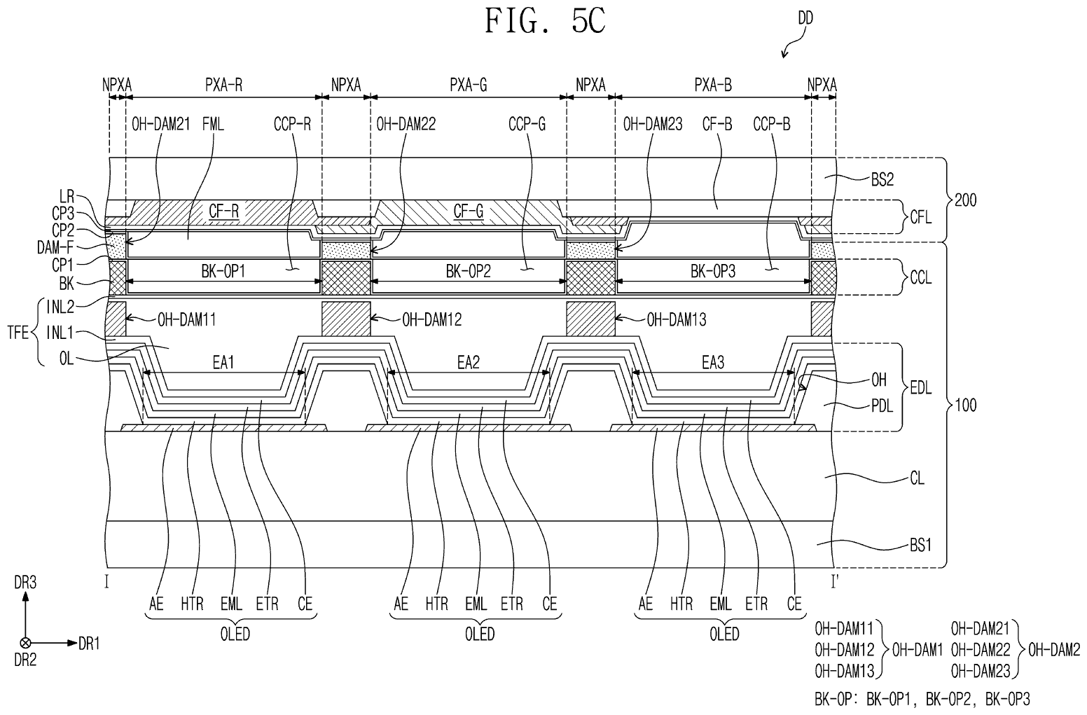

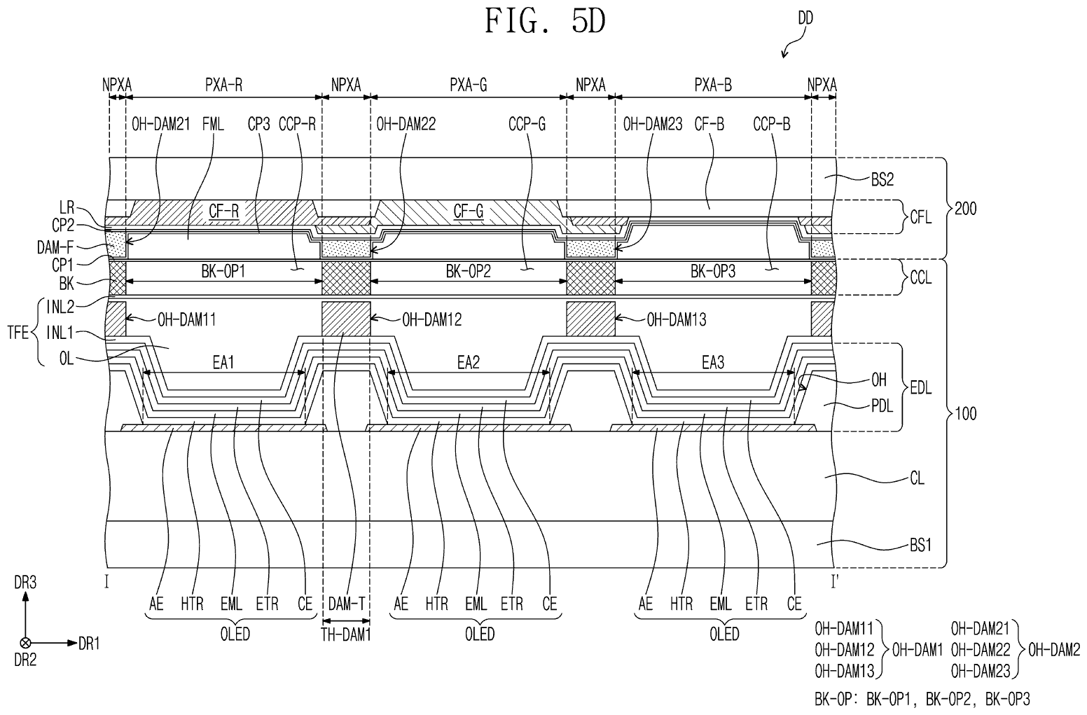

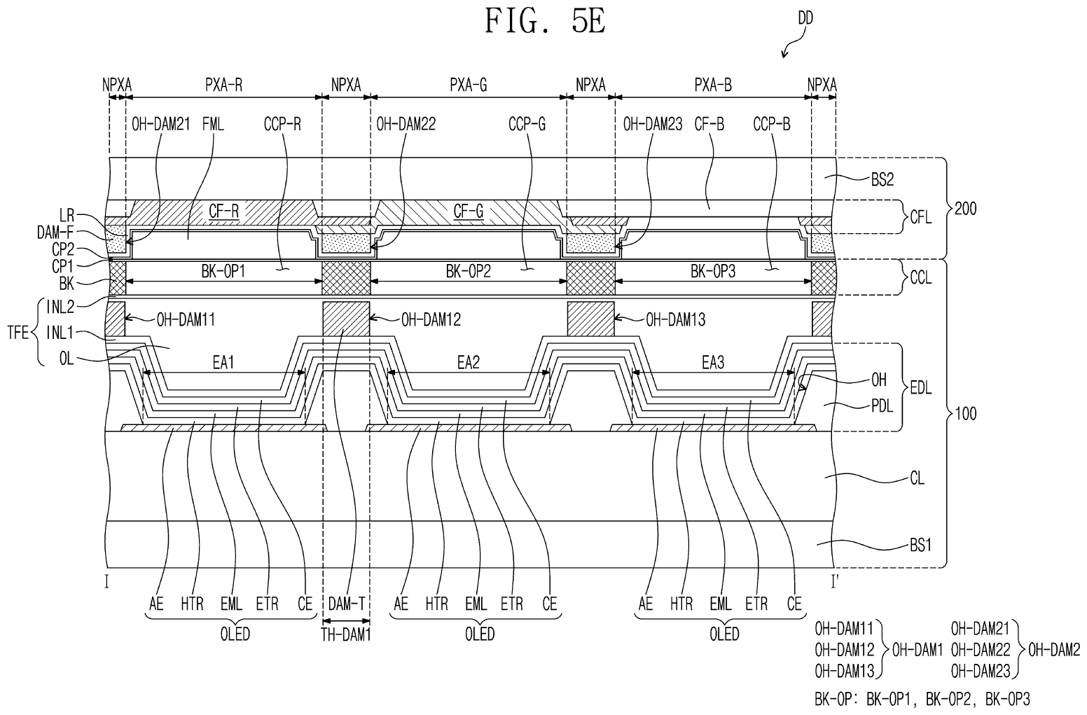

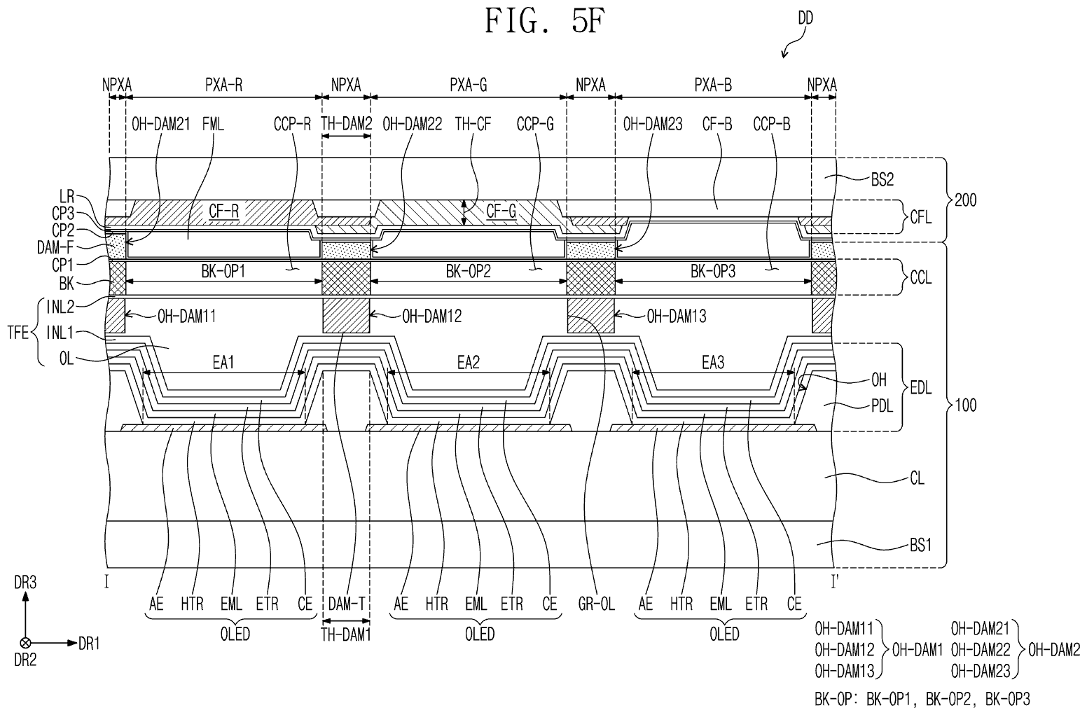

The first pixel area PXA-R, the second pixel area PXA-G, and the third pixel area PXA-B may be defined with respect to the second display substrate 200 (refer to FIG. 5A). A peripheral area NPXA may be defined between the first, second, and third pixel areas PXA-R, PXA-G, and PXA-B. The peripheral area NPXA may define a boundary of the first, second, and third pixel areas PXA-R, PXA-G, and PXA-B and may prevent a color mixture between the first, second, and third pixel areas PXA-R, PXA-G, and PXA-B.

Among the pixels PX11 to PXnm (refer to FIG. 3) of the first display substrate 100 (refer to FIG. 3), a pixel overlapping the first pixel area PXA-R of the second display substrate 200 (refer to FIG. 5A) may be defined as a first pixel, a pixel overlapping the second pixel area PXA-G of the second display substrate 200 (refer to FIG. 5A) may be defined as a second pixel, and a pixel overlapping the third pixel area PXA-B of the second display substrate 200 (refer to FIG. 5A) may be defined as a third pixel. However, as described later, the first pixel, the second pixel, and the third pixel may have substantially the same configuration without being distinguished from each other. The first pixel, the second pixel, and the third pixel may not be distinguished from each other and may be defined as the pixels respectively overlapping the first pixel area PXA-R, the second pixel area PXA-G, and the third pixel area PXA-B.

Each of the first pixel, the second pixel, and the third pixel may include a light emitting element OLED (refer to FIG. 5A), the light emitting elements OLED (refer to FIG. 5A) of the first pixel, the second pixel, and the third pixel may emit source lights having the same color. However, the light emitting elements OLED (refer to FIG. 5A) of the first pixel, the second pixel, and the third pixel may have the same size as each other or different sizes from each other.

The source lights generated by the light emitting elements OLED (refer to FIG. 5A) of the first pixel, the second pixel, and the third pixel may be converted to lights having different colors from each other while passing through the first pixel area PXA-R, the second pixel area PXA-G, and the third pixel area PXA-B and then may be emitted. The source light generated by the first display substrate 100 may be converted to the light having a color different from the color of the source light in the second display substrate 200 (refer to FIG. 5A) described later.

Referring to FIG. 4, the first pixel area PXA-R and the third pixel area PXA-B may be arranged in the same row, and the second pixel area PXA-G may be arranged in a row different from the row in which the first pixel area PXA-R and the third pixel area PXA-B are arranged. The second pixel area PXA-G may have the largest size, and the third pixel area PXA-B may have the smallest size, however, the disclosure should not be limited thereto or thereby. In the embodiment, each of the first pixel area PXA-R, the second pixel area PXA-G, and the third pixel area PXA-B has a substantially square shape, however, the arrangement and size of the pixel areas should not be particularly limited.

The arrangement of the first pixel area PXA-R, the second pixel area PXA-G, and the third pixel area PXA-B disposed in the unit pixels PXU shown in FIG. 4 is an example, and the disclosure should not be limited thereto or thereby. According to an embodiment, the first pixel area PXA-R, the second pixel area PXA-G, and the third pixel area PXA-B may be arranged in the same row along the first direction DR1. As an example, the pixel areas PXA-R, PXA-G, and PXA-B may be arranged in a stripe arrangement, a pentile (PENTILE™) arrangement or in a diamond (Diamond Pixel™) arrangement. The arrangement of the first pixel area PXA-R, second pixel area PXA-G, and third pixel area PXA-B may be changed depending on the unit pixels PXU.

FIG. 5A is a schematic cross-sectional view taken along line I-I′ of FIG. 4 according to an embodiment. FIG. 5A shows a cross-section of portions of the first, second, and third pixel areas PXA-R, PXA-G, and PXA-B of the display device DD taken along the line I-I′ of FIG. 4.

Referring to FIG. 5A, the first display substrate 100 may include a first base layer BS1, a circuit layer CL, a light emitting element layer EDL, an encapsulation layer TFE, a light control layer CCL, and a second dam pattern DAM-F.

The first base layer BS1 may be disposed at a lowermost position of the first display substrate 100. The first base layer BS1 may provide a base surface on which components except the first base layer BS1 included in the first display substrate 100 may be stacked each other.

The first base layer BS1 may include a synthetic resin layer or a glass layer. The first base layer BS1 may include a first synthetic resin layer, a second synthetic resin layer, and an inorganic layer disposed between the first and second synthetic resin layers. The synthetic resin layer may include a thermosetting resin. By way of example, the synthetic resin layer may be a polyimide-based resin layer, however, it should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin.

The circuit layer CL may be disposed on the first base layer BS1. The circuit layer CL may include an insulating layer, a semiconductor pattern, a conductive pattern, and a signal line. An insulating layer, a semiconductor layer, and a conductive layer may be formed on the first base layer BS1 by a coating or depositing process. Accordingly, the insulating layer, the semiconductor layer, and the conductive layer may be selectively patterned through several photolithography processes. Accordingly, the semiconductor pattern, the conductive pattern, and the signal line included in the circuit layer CL may be formed. The circuit layer CL may include a transistor, a buffer layer, and insulating layers.

The light emitting element layer EDL may be disposed on the circuit layer CL and may include the light emitting element OLED and a pixel definition layer PDL.

The light emitting element OLED may include a first electrode AE, a second electrode CE facing the first electrode AE, and a light emitting layer EML disposed between the first electrode AE and the second electrode CE. The light emitting element OLED may overlap the first, second, and third pixel areas PXA-R, PXA-G, and PXA-B and may emit the source light. The light emitting layer EML included in the light emitting element OLED may include an organic light emitting material or a quantum dot as its light emitting material. The light emitting element OLED may further include a hole transport region HTR and/or an electron transport region ETR.

The pixel definition layer PDL may be disposed on the circuit layer CL and may cover a portion of the first electrode AE. Light emitting openings OH may be defined through the pixel definition layer PDL to overlap the first, second, and third pixel areas PXA-R, PXA-G, and PXA-B. At least a portion of the first electrode AE may be exposed through a corresponding light emitting opening of the light emitting openings OH of the pixel definition layer PDL.

First, second, and third light emitting areas EA1, EA2, and EA3 may be defined to correspond to portions of the first electrode AE, which are exposed through the light emitting openings OH of the pixel definition layer PDL. An area except the first, second, and third light emitting areas EA1, EA2, and EA3 may be defined as a non-light-emitting area. The expression “Two components correspond to each other.” may mean that the two components overlap each other when viewed in the third direction DR3 that is a thickness direction of the display device DD, but should not be limited to having the same size as each other.

The first, second, and third light emitting areas EA1, EA2, and EA3 may overlap the first, second, and third pixel areas PXA-R, PXA-G, and PXA-B, respectively. When viewed in the plane, sizes of the first, second, and third pixel areas PXA-R, PXA-G, and PXA-B may be greater than sizes of the first, second, and third light emitting areas EA1, EA2, and EA3, however, this is an example. The sizes of the pixel areas PXA-R, PXA-G, and PXA-B may be substantially the same as the sizes of the light emitting areas EA1, EA2, and EA3.

The first electrode AE may be disposed on the circuit layer CL. The first electrode AE may be an anode or a cathode. According to an embodiment, the first electrode AE may be a pixel electrode, or the first electrode AE may be a transmissive electrode, a transflective electrode, or a reflective electrode.

The hole transport region HTR may be disposed on the first electrode AE. The hole transport region HTR may be commonly disposed in the first, second, and third light emitting areas EA1, EA2, and EA3 and the non-light-emitting area. A common layer such as the hole transport region HTR may be disposed to overlap the unit pixels PXU in the display area DA shown in FIG. 4, however, it should not be limited thereto or thereby. According to an embodiment, the hole transport region HTR may be divided into plural portions to respectively correspond to the first, second, and third light emitting areas EA1, EA2, and EA3. The hole transport region HTR may include at least one of a hole transport layer, a hole injection layer, and an electron blocking layer.

The light emitting layer EML may be disposed on the hole transport region HTR. The light emitting layer EML may be commonly disposed in the first, second, and third light emitting areas EA1, EA2, and EA3 and the non-light-emitting area. The light emitting layer EML may be disposed to overlap (e.g., entirely overlap) the hole transport region HTR and the electron transport region ETR, however, the disclosure should not be limited thereto or thereby. According to an embodiment, the light emitting layer EML may be disposed in the light emitting opening OH. For example, the light emitting layer EML may be divided into plural portions to respectively correspond to each of the first, second, and third light emitting areas EA1, EA2, and EA3, which are distinguished from each other by the pixel definition layer PDL.

The light emitting layer EML may generate the source light. In the display device DD, the light emitting layer EML may emit a blue light, and thus, the blue light may be the source light. In the case where the light emitting layer EML is divided into plural portions to be disposed corresponding to the first, second, and third light emitting areas EA1, EA2, and EA3, all the first, second, and third light emitting areas EA1, EA2, and EA3 of the light emitting layer EML may emit the blue light, or the first, second, and third light emitting areas EA1, EA2, and EA3 may emit lights in different wavelengths ranges from each other.

The light emitting layer EML may have a single-layer structure of a single material, a single-layer structure of plural different materials, or a multi-layer structure of layers formed of different materials. The light emitting layer EML may include a fluorescent or phosphorescent material. According to an embodiment, the light emitting layer EML of the light emitting element may include an organic light emitting material, a metal organic complex, or a quantum dot as its light emitting material.

The electron transport region ETR may be disposed on the light emitting layer EML. The electron transport region ETR may include at least one of an electron injection layer, an electron transport layer, and a hole blocking layer. The electron transport region ETR may be disposed as a common layer to overlap (e.g., entirely overlap) the first, second, and third light emitting areas EA1, EA2, and EA3 and the pixel definition layer PDL, however, the disclosure should not be limited thereto or thereby. According to an embodiment, the electron transport region ETR may be divided into plural portions, and the divided portions of the electron transport region ETR may be arranged to respectively correspond to the first, second, and third light emitting areas EA1, EA2, and EA3.

The second electrode CE may be disposed on the electron transport region ETR. The second electrode CE may be a common electrode. The second electrode CE may be a cathode or an anode, however, it should not be limited thereto or thereby. As an example, in case that the first electrode AE is the anode, the second electrode CE may be the cathode, and in case that the first electrode AE is the cathode, the second electrode CE may be the anode. The second electrode CE may be a transmissive electrode, a transflective electrode, or a reflective electrode.

The encapsulation layer TFE may be disposed on the light emitting element layer EDL and may cover the light emitting element OLED. The encapsulation layer TFE may be commonly disposed in the unit pixels PXU (refer to FIG. 4). The encapsulation layer TFE may include a first inorganic layer INL1, an organic layer OL, and a second inorganic layer INL2, however, the disclosure should not be limited thereto or thereby. The encapsulation layer TFE may further include inorganic layers and organic layers. The encapsulation layer TFE may prevent external moisture or oxygen from entering the light emitting layer EML and may prevent reliability of the display device DD from being deteriorated.

The first inorganic layer INL1 may be disposed on the second electrode CE and may cover the light emitting element OLED. The first inorganic layer INL1 may prevent the external moisture or oxygen from entering the light emitting layer EML. The first inorganic layer INL1 may include silicon nitride, silicon oxide, or a compound thereof. The first inorganic layer INL1 may be formed through a deposition process.

The organic layer OL may be disposed on the first inorganic layer INL1. The organic layer OL may provide a flat surface on the first inorganic layer INL1. Uneven portions may be formed on the first inorganic layer INL1 or particles formed in a manufacturing process of the display device DD may remain on the first inorganic layer INL1. The organic layer OL may be disposed on the first inorganic layer INL1, and thus, the organic layer OL may prevent the uneven portions or particles on the first inorganic layer INL1 from exerting influences on the components formed on the organic layer OL. The organic layer OL may include an organic material and may be formed through a solution process, such as a spin coating process, a slit coating process, an inkjet process, or the like within the spirit and the scope of the disclosure.

In a process of forming the organic layer OL, an overflow phenomenon in which the organic layer OL is formed beyond the display area DA may occur since a solution containing an organic material has flowability. In this case, the display device DD may further include dam patterns that restrain the flowability of the solution including the organic material, and thus, the occurrence of the overflow phenomenon may be prevented.

The second inorganic layer INL2 may be disposed on the organic layer OL to cover the organic layer OL. The second inorganic layer INL2 may include silicon nitride, silicon oxide, or a compound thereof. Since the organic layer OL provides the flat surface, the second inorganic layer INL2 may be stably formed on a relatively flat surface in case that compared with a case where the second inorganic layer INL2 is disposed directly on the first inorganic layer INL1. The second inorganic layer INL2 may be formed through a deposition process. A hydrogen plasma treatment may be further performed on a surface of the organic layer OL between the forming of the organic layer OL and the forming of the second inorganic layer INL2. In case that the surface of the organic layer OL is hydrogen-plasma treated, the second inorganic layer INL2 may be more uniformly formed on the organic layer OL.

A first dam pattern DAM-T may be disposed on the pixel definition layer PDL. The first dam pattern DAM-T may be disposed directly on the pixel definition layer PDL. The first dam pattern DAM-T may overlap the peripheral area NPXA and may be disposed between the pixel definition layer PDL and the light emitting element OLED. A lower surface of the first dam pattern DAM-T may be in contact with the pixel definition layer PDL. An upper surface and a side surface of the first dam pattern DAM-T may be surrounded by the light emitting element OLED.

A shape of the first dam pattern DAM-T when viewed in the plane may vary as needed. As an example, the shape of the first dam pattern DAM-T when viewed in the plane may be discontinuous. As an example, the shape of the first dam pattern DAM-T when viewed in the plane may overlap the peripheral area NPXA of FIG. 4, and a portion of the first dam pattern DAM-T, which is disposed between the first, second, and third pixel areas PXA-R, PXA-G, and PXA-B, may be disconnected.

The first dam pattern DAM-T may be provided in plural. The first dam patterns DAM-T may overlap the peripheral area NPXA. However, the arrangement of the first dam patterns DAM-T should not be limited to the structure shown in FIG. 5A. As an example, the first dam patterns DAM-T may be disposed to overlap only a portion of the peripheral area NPXA, and the other portion of the peripheral area NPXA may not overlap the first dam patterns DAM-T.

The first dam pattern DAM-T may have a multi-layer structure. The first dam pattern DAM-T may include at least one block.

A first dam opening OH-DAM1 may be defined through the first dam pattern DAM-T to overlap the light emitting opening OH. The first dam opening OH-DAM1 may include a (1-1)th dam opening OH-DAM11 that overlaps the first pixel area PXA-R, a (1-2)th dam opening OH-DAM12 that overlaps the second pixel area PXA-G, and a (1-3)th dam opening OH-DAM13 that overlaps the third pixel area PXA-B. The organic layer OL may be disposed in the first dam opening OH-DAM1. The organic layer OL may be filled in the first dam opening OH-DAM1 and may have a flat upper surface.

The transmittance of the first dam pattern DAM-T for a source light L1 may be lower than that of each of the encapsulation layer TFE, the light emitting element OLED, and the pixel definition layer PDL. Accordingly, the first dam pattern DAM-T may prevent the source light L1 generated by the light emitting element OLED that overlaps one pixel area among the pixel areas PXA-R, PXA-G, and PXA-B from traveling to the other pixel areas among the pixel areas PXA-R, PXA-G, and PXA-B, which are adjacent to the one pixel areas.

The first dam pattern DAM-T may include a black coloring agent. The black coloring agent may include a black dye or a black pigment. According to an embodiment, the black coloring agent may include a metal material, such as carbon black, chromium, or an oxide thereof. However, a material for the first dam pattern DAM-T should not be limited thereto or thereby, and various materials with a low transmittance with respect to source lights L1 and L2 may be used.

The first dam pattern DAM-T may have a width TH-DAM1 equal to or greater than about 15 μm. In case that the width TH-DAM1 of the first dam pattern DAM-T is smaller than about 15 μm, the first dam pattern DAM-T may not prevent the source light L1 from traveling to the pixel areas PXA-R, PXA-G, and PXA-B adjacent thereto after passing through the first dam pattern DAM-T.

FIG. 5A shows a structure in which the width TH-DAM1 of the first dam pattern DAM-T is similar to a width of a bank BK, however, the width TH-DAM1 of the first dam pattern DAM-T may be different from the width of the bank BK. As an example, the width TH-DAM1 of the first dam pattern DAM-T may be smaller or greater than the width of the bank BK.

The first dam pattern DAM-T may prevent the source light L1 generated by the light emitting element OLED that overlaps the first pixel area PXA-R from traveling to the second and third pixel areas PXA-G and PXA-B adjacent to the first pixel area PXA-R. The first dam pattern DAM-T having the low transmittance with respect to the source light L1 may be disposed in the peripheral area NPXA corresponding to a boundary between the first, second, and third pixel areas PXA-R, PXA-G, and PXA-B.

For example, the first dam pattern DAM-T may serve as a barrier wall. The barrier wall may block a path through which the source light L1 generated from one pixel area PXA-R travels to the pixel areas PXA-G and PXA-B adjacent to the one pixel area PXA-R to prevent a color mixture from occurring between the pixels adjacent to each other. This may be applied to the source light generated by the light emitting element OLED overlapping the second and third pixel areas PXA-G and PXA-B.

The light control layer CCL may be disposed on the encapsulation layer TFE. The light control layer CCL may include the bank BK, light control patterns CCP-R, CCP-G, and CCP-B, and a first capping layer CP1.

The bank BK may be disposed on the first dam pattern DAM-T. The bank BK may be disposed on the second inorganic layer INL2. The bank BK may be provided with openings BK-OP defined therethrough. The openings BK-OP corresponding to the first, second, and third pixel areas PXA-R, PXA-G, and PXA-B may be defined as first, second, and third openings BK-OP1, BK-OP2, and BK-OP3, respectively.

The bank BK may be a pattern with a black color, for example, a black matrix. The bank BK may include a black coloring agent. The black coloring agent may include a black dye or a black pigment. According to an embodiment, the black coloring agent may include a metal material, such as carbon black, chromium, or an oxide thereof.

First, second, and third light control patterns CCP-R, CCP-G, and CCP-B may be disposed in the openings BK-OP, respectively. The first, second, and third light control patterns CCP-R, CCP-G, and CCP-B may change optical properties of the source light and may convert the source light to an output light L3. In detail, the first and second light control patterns CCP-R and CCP-G may absorb the source light and may generate the output light L3 having a color different from that of the source light. The third light control pattern CCP-B may transmit or scatter a portion of the source light incident thereto. Accordingly, the light exiting through the third light control pattern CCP-B may have substantially the same color as that of the source light. As described above, the third light control pattern CCP-B may have an optical function different from that of the first and second light control patterns CCP-R and CCP-G.

Each of the first and second light control patterns CCP-R and CCP-G may include a base resin and quantum dots mixed with (or dispersed in) the base resin. In the embodiment, the first and second light control patterns CCP-R and CCP-G may be defined as a quantum dot pattern and may include different quantum dots. The base resin may be a medium in which the quantum dots are dispersed and may include various resin compositions that are generally referred to as a binder. However, it should not be limited thereto or thereby. In the disclosure, any medium in which the quantum dots are dispersed may be used as the base resin regardless of its name, additional functions, constituent materials, etc. The base resin may be a polymer resin. For example, the base resin may be an acrylic-based resin, a urethane-based resin, a silicone-based resin, or an epoxy-based resin. The base resin may be a transparent resin.

The quantum dots may be particles that change a wavelength of light incident thereto. The quantum dots are a material having a crystal structure of several nanometers in size, contain hundreds to thousands of atoms, and exhibit a quantum confinement effect, which results in an increased energy band gap due to their small size. In case that a light with a wavelength carrying higher energy than the band gap is incident into the quantum dots, the quantum dots absorb the light and become excited, and the quantum dots emit a light of a given wavelength and fall to a ground state. The emitted light of the given wavelength has an energy value corresponding to the band gap. The light-emitting property of the quantum dots due to the quantum confinement effect may be controlled by adjusting the size and the composition of the quantum dots. According to an embodiment, a diameter of the quantum dot may be in a range of about 1 nm to about 10 nm.

The quantum dots may be synthesized by a wet chemical process, a metal organic chemical vapor deposition process, a molecular beam epitaxy process, or similar processes. The wet chemical process is a method of growing quantum dot particle crystals after mixing an organic solvent with a precursor material. In case that the crystals grow, the organic solvent may naturally serve as a dispersant coordinated to the surface of the quantum dot crystal and may control the growth of the crystals. Accordingly, the wet chemical process may be easier than vapor deposition methods such as the metal organic chemical vapor deposition (MOCVD) process or the molecular beam epitaxy (MBE) and may control the growth of quantum dot particles through a low-cost process.

The quantum dots may include a group III-VI compound, a group II-VI compound, a group III-V compound, a group I-III-VI compound, a group IV-VI compound, a group IV element, a group IV compound, or an arbitrary combination thereof.

The group III-VI compound may include a binary compound such as GaS, GazS₃, GaSe, Ga₂Se₃, GaTe, InS, InSe, In₂Se₃, and/or InTe, a ternary compound such as InGaS₃ and/or InGaSe₃, or an arbitrary combination thereof.

The group II-VI compound may include a binary compound such as CdS, CdSe, CdTe, ZnS, ZnSe, ZnTe, ZnO, HgS, HgSe, HgTe, MgSe, and/or MgS, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS, a quaternary compound such as CdZnSeS, CdZnSeTe, CdZnSTe, CdHgSeS, CdHgSeTe, CdHgSTe, HgZnSeS, HgZnSeTe, and/or HgZnSTe, or an arbitrary combination thereof. The group II-VI compound may further include a group I metal and/or a group IV element. The group I-II-VI compound may be selected from CuSnS or CuZnS, and the group II-IV-VI compound may be selected from ZnSnS. The group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The group III-V compound may include a binary compound such as GaN, GaP, GaAs, GaSb, AlN, AIP, AlAs, AlSb, InN, InP, InAs, and/or InSb, a ternary compound such as GaNP, GaNAs, GaNSb, GaPAs, GaPSb, AlNP, AlNAs, AlNSb, AlPAs, AlPSb, InGaP, InNP, InAIP, InNAs, InNSb, InPAs, and/or InPSb, a quaternary compound such as GaAINP, GaAINAs, GaAINSb, GaAlPAs, GaAlPSb, GalnNP, GalnNAs, GaInNSb, GalnPAs, GaInPSb, InAINP, InAINAs, InAINSb, InAlPAs, and/or InAlPSb, or an arbitrary combination thereof. The group III-V compound may further include a group II element. For instance, the group III-V compound that further may include the group II element may include InZnP, InGaZnP, InAlZnP, etc.

The group I-III-VI compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and/or AgAlO₂, a quaternary compound such as AgInGaS₂, and/or AgInGaSe₂, or an arbitrary combination thereof.

The group IV-VI compound may include a binary compound such as SnS, SnSe, SnTe, PbS, PbSe, and/or PbTe, a ternary compound such as SnSeS, SnSeTe, SnSTe, PbSeS, PbSeTe, PbSTe, SnPbS, SnPbSe, and/or SnPbTe, a quaternary compound such as SnPbSSe, SnPbSeTe, and/or SnPbSTe, or an arbitrary combination thereof.

The group II-IV-V compound may include a ternary compound selected from the group consisting of ZnSnP, ZnSnP₂, ZnSnAs₂, ZnGeP₂, ZnGeAs₂, CdSnP₂, CdGeP₂, and a mixture thereof.

The group IV element or the group IV compound may include a single-element compound such as Si or Ge, a binary compound such as SiC or SiGe, or an arbitrary combination thereof.

Each element included in a multi-element compound, such as the binary compound, the ternary compound, or the quaternary compound, may be present in the particles at a uniform or non-uniform concentration. For example, the above chemical formula means the types of elements included in the compound, and an element ratio in the compound may be variable. As an example, AgInGaS₂ may mean AgInₓGa₁₋ₓS₂ (x is a real number between 0 to 1).

The quantum dot may have a single structure in which the concentration of each element in the quantum dot is substantially uniform, or a core-shell dual structure. For example, a material included in the core and a material included in the shell may be different from each other.

The shell of the quantum dot may serve as a protective layer to prevent chemical modification of the core and to maintain semiconductor properties and/or may serve as a charging layer to impart electrophoretic properties to the quantum dot. The shell may have a single-layer or multi-layer structure. The concentration of elements existing in the shell may have the concentration gradient that is lowered as a distance from a center decreases in an interface between the core and the shell. (In the core/shell structure, the concentration of elements existing in the shell may have a concentration gradient that is lowered as a distance from the core decreases.)

The shell of the quantum dots may include metal oxides, non-metal oxides, compounds, or combinations thereof. The metal oxides or non-metal oxides may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, a ternary compound, such as MgAl₂O₄, CoFe₂O₄, NiFe₂O₄, and CoMn₂O₄, or an arbitrary combination thereof. The compounds may include the group III-VI compound, the group II-VI compound, the group III-V compound, the group I-III-VI compound, the group IV-VI compound, or an arbitrary combination thereof. As an example, the compounds may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or an arbitrary combination thereof.

Each element included in a multi-element compound, such as the binary compound, or the ternary compound, may be present in the particles at a uniform or non-uniform concentration. For example, the above chemical formula means the types of elements included in the compound, and an element ratio in the compound may be variable.

The quantum dots may have a full width at half maximum (FWHM) of a light emission wavelength spectrum of about 45 nm or less, for example about 40 nm or less, and for example about 30 nm or less. The color purity and the color reproducibility may be improved in this range. Since the light emitted through the quantum dots may be emitted in all directions, an optical viewing angle may be improved.

The quantum dots may have a spherical shape, a pyramidal shape, a multi-arm shape, or cubic nanoparticles, nanotubes, nanowires, nanofibers, nanoplatelets, or the like within the spirit and the scope of the disclosure.

Since the energy band gap may be adjusted by controlling the size of the quantum dot or the element ratio in the compounds for the quantum dot, lights having one or more suitable wavelengths may be obtained from a quantum dot light-emitting layer. Accordingly, as the quantum dots described above, for example, the quantum dots having different sizes or having the compounds with different element ratios from each other, are used, the light emitting element that emits the lights of one or more suitable wavelengths may be implemented. In detail, the size of the quantum dot and the element ratio of the compounds for the quantum dot may be selected to emit the red, green and/or blue lights. The quantum dot may be configured to emit a white light by combination of the lights having various colors.

According to an embodiment, the first light control pattern CCP-R may be a red quantum dot pattern that absorbs the source light and generates the red light, and the second light control pattern CCP-G may be a green quantum dot pattern that absorbs the source light and generates the green light. The first light control pattern CCP-R and the second light control pattern CCP-G may further include scattering particles.

The third light control pattern CCP-B may include scattering particles mixed with (or dispersed in) the organic material. The third light control pattern CCP-B may be a scattering pattern that scatters the source light. The scattering particles may be particles having a relatively large density or given gravity. The scattering particles may include titanium oxide (TiO₂) or silica-based nanoparticles.

The first capping layer CP1 may be disposed on the bank BK and the first, second, and third light control patterns CCP-R, CCP-G, and CCP-B. The first capping layer CP1 may be in contact with the first, second, and third light control patterns CCP-R, CCP-G, and CCP-B. The first capping layer CP1 may encapsulate the bank BK and the first, second, and third light control patterns CCP-R, CCP-G, and CCP-B to prevent the bank BK and the first, second, and third light control patterns CCP-R, CCP-G, and CCP-B from being damaged in a subsequent process. The first capping layer CP1 may have a single-layer or multi-layer structure. The first capping layer CP1 may include silicon oxide, silicon nitride, silicon oxynitride, or the like within the spirit and the scope of the disclosure.

The second dam pattern DAM-F may be disposed on the bank BK and may overlap the peripheral area NPXA. The second dam pattern DAM-F may be disposed directly on the first capping layer CP1. The second dam pattern DAM-F may be disposed between color filters CF-R, CF-G, and CF-B and the bank BK.

A second dam opening OH-DAM2 may be defined through the second dam pattern DAM-F to overlap the first dam opening OH-DAM1. The second dam opening OH-DAM2 may include a (2-1)th dam opening OH-DAM21 that overlaps the first pixel area PXA-R and the (1-1)th dam opening OH-DAM11, a (2-2)th dam opening OH-DAM22 that overlaps the second pixel area PXA-G and the (1-2)th dam opening OH-DAM12, and a (2-3)th dam opening OH-DAM23 that overlaps the third pixel area PXA-B and the (1-3)th dam opening OH-DAM13. A filling material FML may be filled in the second dam opening OH-DAM2. The filling material FML may include an epoxy-based organic material.

The transmittance of the second dam pattern DAM-F for the source light L2 and the output light L3 may be lower than that of the filling material FML. Accordingly, the second dam pattern DAM-F may prevent the source light L2 generated by the light emitting element OLED adjacent to one pixel area among the pixel areas PXA-R, PXA-G, and PXA-B from traveling to the other pixel areas among the pixel areas PXA-R, PXA-G, and PXA-B, which are adjacent to the one pixel area. The second dam pattern DAM-F may prevent the output light L3 converted by the light control patterns CCP-R, CCP-G, and CCP-B respectively overlapping the pixel areas PXA-R, PXA-G, and PXA-B from traveling to adjacent pixel areas PXA-R, PXA-G, and PXA-B.

The second dam pattern DAM-F may include a black coloring agent. The black coloring agent may include a black dye or a black pigment. According to an embodiment, the black coloring agent may include a metal material, such as carbon black, chromium, or an oxide thereof. However, a material for the second dam pattern DAM-F should not be limited thereto or thereby, and various materials with a low transmittance with respect to the source light L2 and the output light L3 may be used.

The second dam pattern DAM-F may have a width TH-DAM2 equal to or greater than about 15 μm. In case that the width TH-DAM2 of the second dam pattern DAM-F is smaller than about 15 μm, the second dam pattern DAM-F may not prevent the source light L2 and the output light L3 from traveling to the pixel areas PXA-R, PXA-G, and PXA-B adjacent thereto after passing through the second dam pattern DAM-F.

The second dam pattern DAM-F may serve as a barrier wall. The barrier wall may block a path through which the source light L2 and the output light L3 generated from one pixel area PXA-R travel to the pixel areas PXA-G and PXA-B adjacent to the one pixel area PXA-R to prevent a color mixture from occurring between the pixels adjacent to each other. This may be applied to the source light generated by the light emitting element OLED overlapping the second and third pixel areas PXA-G and PXA-B and the output light L3 converted by the light control patterns CCP-R, CCP-G, and CCP-B.

The second dam pattern DAM-F may have a multi-layer structure. The second dam pattern DAM-F may include at least one block. The second dam pattern DAM-F may have a shape in which one or more blocks may be stacked each other.

A second capping layer CP2 may be disposed on the second dam pattern DAM-F and the first capping layer CP1. The second capping layer CP2 may encapsulate the second dam pattern DAM-F to prevent the second dam pattern DAM-F from being damaged in a subsequent process.

The second display substrate 200 may include a second base layer BS2, a color filter layer CFL, a low refractive index layer LR, and a third capping layer CP3.

The second display substrate 200 may be disposed above the first display substrate 100 and may be spaced apart from the first display substrate 100. The cell gap GP (refer to FIG. 2) may be a space between the first display substrate 100 and the second display substrate 200 spaced apart from the first display substrate 100. The cell gap GP (refer to FIG. 2) may be maintained in an empty space or may be filled with a gas. The cell gap GP may be filled with a filling material FML.

The second base layer BS2 may provide a base surface on which the color filter layer CFL is disposed. The second base layer BS2 may include a synthetic resin layer or a glass layer. The synthetic resin layer may include a thermosetting resin. The synthetic resin layer may be a polyimide-based resin layer, however, it should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. The second base layer BS2 may include a glass substrate, a metal substrate, or an organic/inorganic composite material substrate.

The color filter layer CFL may be disposed on a lower surface of the second base layer BS2. The color filter layer CFL may include color filters CF-R, CF-G, and CF-B. The color filters CF-R, CF-G, and CF-B may include first, second, and third color filters CF-R, CF-G, and CF-B that respectively overlap the first, second, and third pixel areas PXA-R, PXA-G, and PXA-B. The first color filter CF-R may transmit a first color light. The second color filter CF-G may transmit a second color light. The third color filter CF-B may transmit a third color light.

In the embodiment, one of the first and second color lights may be a red light, the other of the first and second color lights may be a green light, and the third color light may be a blue light. The first, second, and third color lights may be red, green, and blue lights, respectively. The first, second, and third color filters CF-R, CF-G, and CF-B may be a red color filter, a green color filter, and a blue color filter, respectively.

The first pixel area PXA-R, the second pixel area PXA-G, the third pixel area PXA-B, and the peripheral area NPXA may be defined by the first, second, and third color filters CF-R, CF-G, and CF-B. The peripheral area NPXA may be defined as an area where two or more color filters of the first, second, and third color filters CF-R, CF-G, and CF-B overlap each other. The first pixel area PXA-R may overlap only the first color filter CF-R, the second pixel area PXA-G may overlap only the second color filter CF-G, and the third pixel area PXA-B may overlap only the third color filter CF-B.

In case that two or more color filters overlap each other, the effect of blocking the external light may increase, and the interference of colors or the color mixture between the pixels may be prevented. Therefore, the structure in which two or more color filters overlap each other may correspond to a light blocking structure.

A filter opening may be defined through the second color filter CF-G and the third color filter CF-B to correspond to the first pixel area PXA-R. Similarly, a filter opening may be defined through the first color filter CF-R and the third color filter CF-B to correspond to the second pixel area PXA-G, and a filter opening may be defined through the first color filter CF-R and the second color filter CF-G to correspond to the third pixel area PXA-B.

The low refractive index layer LR may be disposed under or below the color filter layer CFL. The low refractive index layer LR may be disposed on the light control layer CCL. The low refractive index layer LR may be disposed between the color filter layer CFL and the filling material FML. The low refractive index layer LR may be disposed between the light control layer CCL and the color filter layer CFL to serve as an optical functional layer that improves a light extraction efficiency or prevents a reflected light from being incident into the light control layer CCL. The low refractive index layer LR may have a refractive index smaller than that of a layer adjacent thereto. As an example, the low refractive index layer LR may have the refractive index equal to or greater than about 1.0 and equal to or smaller than about 1.5.

The second display substrate 200 may further include the third capping layer CP3. The third capping layer CP3 may be disposed on a lower surface of the low refractive index layer LR. The low refractive index layer LR may be omitted from the second display substrate 200. In this case, the third capping layer CP3 may be directly in contact with the first, second, and third color filters CF-R, CF-G, and CF-B. The third capping layer CP3 may serve as a protective layer that covers the color filters CF-R, CF-G, and CF-B and prevents the color filters CF-R, CF-G, and CF-B from being damaged in the manufacturing process of the display device DD. The third capping layer CP3 may be omitted from the second display substrate 200.

The second display substrate 200 may further include a step-difference compensation layer. The step-difference compensation layer may be disposed on a lower surface of the third capping layer CP3 overlapping the non-display area NDA. The step-difference compensation layer may compensate for a step difference occurring in the second display substrate 200 during processes of forming the first, second, and third color filters CF-R, CF-G, and CF-B and the third capping layer CP3. Accordingly, the sealing member SLM (refer to FIG. 2) may be disposed on the flat surface provided by the step-difference compensation layer, and thus, the second display substrate 200 and the first display substrate 100 may be bonded with each other through a vacuum-pressure process.

The components of the first display substrate 100 shown in FIG. 5A may be formed in the order of the first base layer BS1, the circuit layer CL, the pixel definition layer PDL, the first dam pattern DAM-T, the light emitting element OLED, the encapsulation layer TFE, the bank BK, the light control patterns CCP-R, CCP-G, and CCP-B, the first capping layer CP1, the second dam pattern DAM-F, and the second capping layer CP2. The components of the second display substrate 200 may be formed in the order of the second base layer BS2, the color filter layer CFL, the low refractive index layer LR, and the third capping layer CP3. The first display substrate 100 and the second display substrate 200 may be bonded with each other through the vacuum-pressure process.

FIG. 5B is a schematic cross-sectional view taken along line I-I′ of FIG. 4 according to an embodiment. In FIG. 5B, the same reference numerals denote the same elements in FIG. 5A, and thus, detailed descriptions of the same elements may be omitted.

Referring to FIG. 5B, a light emitting element OLED may be formed on a pixel definition layer PDL. A first dam pattern DAM-T may be disposed on the pixel definition layer PDL. The first dam pattern DAM-T may be disposed above the light emitting element OLED. The first dam pattern DAM-T may be disposed directly on a first inorganic layer INL1. The first dam pattern DAM-T may be disposed between the first inorganic layer INL1 and an organic layer OL.

The first dam pattern DAM-T may be disposed close to a bank BK. In this case, the first dam pattern DAM-T may effectively prevent a source light generated from one pixel area of pixel areas PXA-R, PXA-G, and PXA-B from traveling to the other pixel areas of the pixel areas PXA-R, PXA-G, and PXA-B, which are adjacent to the one pixel area. As an example, a source light L1 (refer to FIG. 5A) generated from a first pixel area PXA-R may be prevented from traveling to a second light control pattern CCP-G of a second pixel area PXA-G adjacent to the first pixel area PXA-R.

Components of a first display substrate 100 may be formed in the order of a first base layer BS1, a circuit layer CL, the pixel definition layer PDL, the light emitting element OLED, the first inorganic layer INL1, the first dam pattern DAM-T, the organic layer OL, a second inorganic layer INL2, the bank BK, light control patterns CCP-R, CCP-G, and CCP-B, a first capping layer CP1, a second dam pattern DAM-F, and a second capping layer CP2. Components of a second display substrate 200 may be formed in the order of a second base layer BS2, a color filter layer CFL, a low refractive index layer LR, and a third capping layer CP3. The first display substrate 100 and the second display substrate 200 may be bonded with each other through a vacuum-pressure process.

FIG. 5C is a schematic cross-sectional view taken along line I-I′ of FIG. 4 according to an embodiment. In FIG. 5C, the same reference numerals denote the same elements in FIGS. 5A and 5B, and thus, detailed descriptions of the same elements may be omitted.

Referring to FIG. 5C, a first capping layer CP1 may cover a bank BK. A second dam pattern DAM-F may be disposed directly on the first capping layer CP1 and may overlap a peripheral area NPXA. Light control patterns CCP-R, CCP-G, and CCP-B may be disposed directly on the first capping layer CP1 and may overlap pixel areas PXA-R, PXA-G, and PXA-B. A second capping layer CP2 may be disposed on the light control patterns CCP-R, CCP-G, and CCP-B and the second dam pattern DAM-F and may cover the light control patterns CCP-R, CCP-G, and CCP-B and the second dam pattern DAM-F. The second capping layer CP2 may prevent the light control patterns CCP-R, CCP-G, and CCP-B and the second dam pattern DAM-F from being damaged in a subsequent process.

Components of a first display substrate 100 may be formed in the order of a first base layer BS1, a circuit layer CL, a pixel definition layer PDL, a light emitting element OLED, a first inorganic layer INL1, a first dam pattern DAM-T, an organic layer OL, a second inorganic layer INL2, the bank BK, the first capping layer CP1, the second dam pattern DAM-F, the light control patterns CCP-R, CCP-G, and CCP-B, and the second capping layer CP2. Components of a second display substrate 200 may be formed in the order of a second base layer BS2, a color filter layer CFL, a low refractive index layer LR, and a third capping layer CP3. The first display substrate 100 and the second display substrate 200 may be bonded with each other through a vacuum-pressure process.

FIG. 5D is a schematic cross-sectional view taken along line I-I′ of FIG. 4 according to an embodiment. In FIG. 5D, the same reference numerals denote the same elements in FIGS. 5A and 5B, and thus, detailed descriptions of the same elements may be omitted.

Referring to FIG. 5D, a second display substrate 200 may include a second dam pattern DAM-F. Different from the second dam pattern DAM-F of FIGS. 5A and 5B, the second dam pattern DAM-F of FIG. 5D may be formed together with the second display substrate 200. The second display substrate 200 may include a second base layer BS2, a color filter layer CFL, a low refractive index layer LR, the second dam pattern DAM-F, a second capping layer CP2, and a third capping layer CP3. The third capping layer CP3 may be disposed on a lower surface of the low refractive index layer LR.

The second dam pattern DAM-F may overlap a peripheral area NPXA and may be disposed directly on the third capping layer CP3. The second dam pattern DAM-F may be encapsulated by the second capping layer CP2 and the third capping layer CP3. The second and third capping layers CP2 and CP3 may prevent the second dam pattern DAM-F from being damaged in a subsequent process.

Components of a first display substrate 100 of FIG. 5D may be formed in the order of a first base layer BS1, a circuit layer CL, a pixel definition layer PDL, a light emitting element OLED, a first inorganic layer INL1, a first dam pattern DAM-T, an organic layer OL, a second inorganic layer INL2, a bank BK, light control patterns CCP-R, CCP-G, and CCP-B, and a first capping layer CP1. Components of the second display substrate 200 may be formed in the order of the second base layer BS2, the color filter layer CFL, the low refractive index layer LR, the second capping layer CP2, the second dam pattern DAM-F, and the third capping layer CP3. The first display substrate 100 and the second display substrate 200 may be bonded with each other through a vacuum-pressure process.

FIG. 5E is a schematic cross-sectional view taken along line I-I′ of FIG. 4 according to an embodiment. In FIG. 5E, the same reference numerals denote the same elements in FIGS. 5A and 5B, and thus, detailed descriptions of the same elements may be omitted.

Referring to FIG. 5E, a second display substrate 200 may include a second dam pattern DAM-F. Different from the second dam pattern DAM-F of FIGS. 5A and 5B, the second dam pattern DAM-F of FIG. 5E may be formed together with the second display substrate 200. The second display substrate 200 may include a second base layer BS2, a color filter layer CFL, a low refractive index layer LR, the second dam pattern DAM-F, and a second capping layer CP2.

The second dam pattern DAM-F may overlap a peripheral area NPXA and may be disposed directly on the color filter layer CFL. The low refractive index layer LR may be disposed on the second dam pattern DAM-F and the color filter layer CFL. The low refractive index layer LR may cover the color filter layer CFL and the second dam pattern DAM-F. The second capping layer CP2 may be disposed on the low refractive index layer LR and may cover the low refractive index layer LR. The second capping layer CP2 may prevent the low refractive index layer LR from being damaged in a subsequent process.

Components of a first display substrate 100 of FIG. 5E may be formed in the order of a first base layer BS1, a circuit layer CL, a pixel definition layer PDL, a light emitting element OLED, a first inorganic layer INL1, a first dam pattern DAM-T, an organic layer OL, a second inorganic layer INL2, a bank BK, light control patterns CCP-R, CCP-G, and CCP-B, and a first capping layer CP1. Components of the second display substrate 200 may be formed in the order of the second base layer BS2, the color filter layer CFL, the second dam pattern DAM-F, the low refractive index layer LR, and the second capping layer CP2. The first display substrate 100 and the second display substrate 200 may be bonded with each other through a vacuum-pressure process.

FIG. 5F is a schematic cross-sectional view taken along line I-I′ of FIG. 4 according to an embodiment. A display device DD shown in FIG. 5F may have substantially the same structure and function as those of the display device DD of FIG. 5B except a shape and arrangement of an encapsulation layer TFE and a first dam pattern DAM-T, and thus, details of the same structure and function may be omitted.

Referring to FIG. 5F, a groove GR-OL may be defined in an organic layer OL to overlap a peripheral area NPXA. A first dam pattern DAM-T may be formed in the groove GR-OL. The first dam pattern DAM-T may be disposed between a first inorganic layer INL1 and a second inorganic layer INL2. An upper surface of the first dam pattern DAM-T may be in contact with the second inorganic layer INL2. For example, different from the display devices DD of FIGS. 5A to 5E, the organic layer OL may not be provided on the upper surface of the first dam pattern DAM-T.

Accordingly, the first dam pattern DAM-T may be disposed adjacent to a bank BK and may prevent a source light (refer to L1 of FIG. 5A) generated from one pixel area among pixel areas PXA-R, PXA-G, and PXA-B from traveling to the other pixel areas adjacent to the one pixel area among pixel areas PXA-R, PXA-G, and PXA-B. As an example, the first dam pattern DAM-T may prevent the source light (refer to L1 of FIG. 5A) generated by a light emitting element OLED overlapping a first pixel area PXA-R from traveling to a second light control pattern CCP-G overlapping a second pixel area PXA-G. Therefore, a color mixture between pixels adjacent to each other may be prevented.

A separate process of forming the groove GR-OL corresponding to the first dam pattern DAM-T in the organic layer OL may be further performed to manufacture the display device DD shown in FIG. 5F.

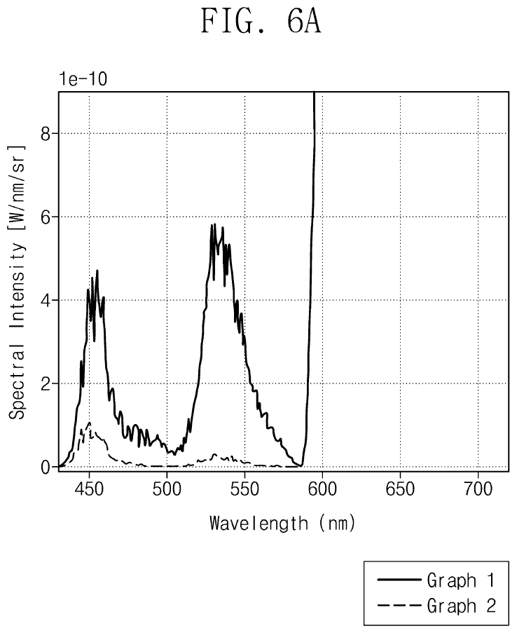

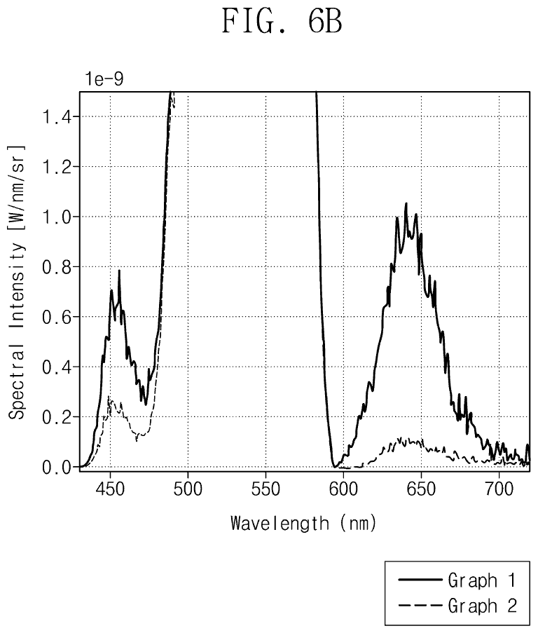

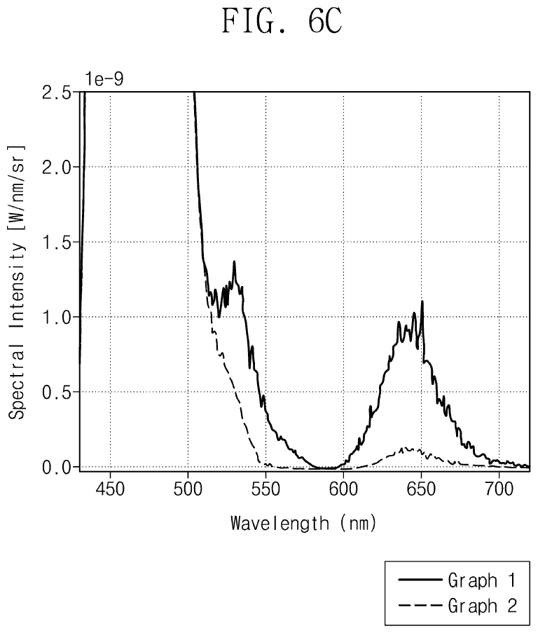

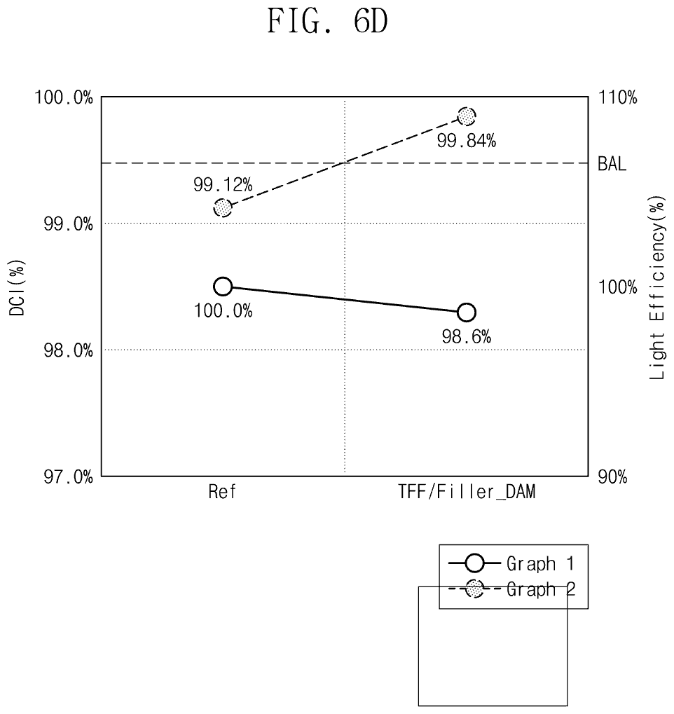

FIG. 6A is a graph illustrating a wavelength measured in a first pixel area as a function of a spectral intensity according to a comparative example and an embodiment example. FIG. 6B is a graph illustrating a wavelength measured in a second pixel area as a function of a spectral intensity according to a comparative example and an embodiment example. FIG. 6C is a graph illustrating a wavelength measured in a third pixel area as a function of a spectral intensity according to a comparative example and an embodiment example.

In FIGS. 6A to 6C, Graph 1 shows a spectral intensity as a function of a wavelength in a display device without the first dam pattern DAM-T and the second dam pattern DAM-F according to the comparative example. Graph 2 shows a spectral intensity as a function of a wavelength in the display device DD of FIG. 5A that may include the first dam pattern DAM-T and the second dam pattern DAM-F according to the embodiment example.

Referring to FIG. 6A, the first pixel area PXA-R may be an area from which a red light (or a first color light) is emitted. Hereinafter, a region where the wavelength is about 650 nm may be a red light region, a region where the wavelength is about 540 nm may be a green light region, and a region where the wavelength is about 450 nm may be a blue light region.

A peak value in the green light region and the blue light region of the comparative example (graph 1) may be greater than that of the embodiment example (graph 2). This means that an amount of the green light and the blue light mixed with the red light is more in the comparative example (graph 1) than in the embodiment example (graph 2).

Referring to FIG. 6B, the second pixel area PXA-G may be an area from which the green light (or a second color light) is emitted.

A peak value in the red light region and the blue light region of the comparative example (graph 1) may be greater than that of the embodiment example (graph 2). This means that an amount of the red light and the blue light mixed with the green light is more in the comparative example (graph 1) than in the embodiment example (graph 2).

Referring to FIG. 6C, the third pixel area PXA-B may be an area from which the blue light (or a third color light) is emitted.

A peak value in the red light region and the green light region of the comparative example (graph 1) may be greater than that of the embodiment example (graph 2). This means that an amount of the green light and the red light mixed with the blue light is more in the comparative example (graph 1) than in the embodiment example (graph 2).

Referring to FIGS. 6A to 6C, it is observed that the first dam pattern DAM-T (refer to FIG. 5A) and the second dam pattern DAM-F (refer to FIG. 5A) of the embodiment example (graph 2) are effective in preventing the color mixture between the pixels adjacent to each other.

The light efficiency of each color light and a DCI color gamut according to the comparative example and the embodiment example are shown in Table 1 below.

TABLE 1

| | Light efficiency | | | | Color |
|---|---|---|---|---|---|
| | Red | Green | Blue | White | gamut |
| | light | light | light | light | DCI |
| Comparative | 100.0% | 100.0% | 100.0% | 100.0% | 99.12% |
| example | | | | | |
| Embodiment | 97.7% | 99.3% | 90.4% | 98.6% | 99.84% |
| example | | | | | |

In Table 1, the light efficiency of the embodiment example may be a ratio of a luminance of light in the embodiment example to a luminance of light in the comparative example. The color gamut is a numerical value that indicates how closely the color displayed by the display device matches an actual color based on DCI-P3 standard. FIG. 6D is a graph showing the light efficiency and the color gamut according to the comparative example and the embodiment example. FIG. 6D graphically illustrates part of the contents of Table 1. Graph 1 of FIG. 6D shows the light efficiency of the white light in the comparative example and the embodiment example. Graph 2 of FIG. 6D shows the color gamut of the comparative example and the embodiment example.

Referring to Table 1 and FIG. 6D, in the embodiment example, it is observed that the light efficiencies of the red, green, blue, and white lights are about 97.7%, about 99.3%, about 90.4%, and about 98.6%, respectively, which are lower than the light efficiencies of about 100% of the comparative example.

As shown in Table 1 and FIG. 6D, the color gamut of the comparative example is about 99.12%, and the color gamut of the embodiment example is about 99.84%. The color gamut is increased by about 0.72% in the embodiment example compared to the comparative example. This means that the display device according to the embodiment example displays more accurate colors. For example, the first dam pattern DAM-T (refer to FIG. 5A) and the second dam pattern DAM-F (refer to FIG. 5A) of the embodiment example prevent the color mixture between the pixels adjacent to each other, and thus, the color gamut is improved.

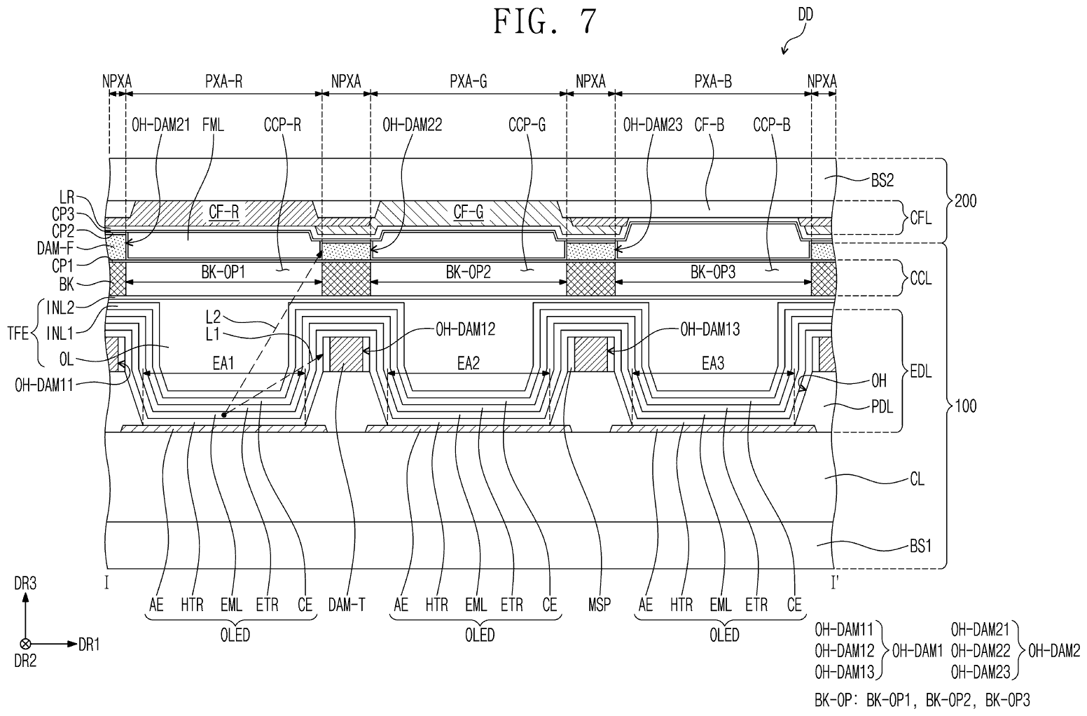

FIG. 7 is a schematic cross-sectional view taken along line I-I′ of FIG. 4 according to an embodiment. In FIG. 7, the same reference numerals denote the same elements in FIG. 5A, and thus, detailed descriptions of the same elements may be omitted.

Referring to FIG. 7, a display device DD may further include a reflective pattern MSP disposed on an inner side surface of a first dam pattern DAM-T. The reflective pattern MSP may reflect a portion of a source light L1 traveling to the first dam pattern DAM-T. The reflective pattern MSP and the first dam pattern DAM-T may prevent the source light L1 from traveling to pixel areas PXA-R, PXA-G, and PXA-B adjacent thereto. By way of example, in case that a width TH-DAM1 (refer to FIG. 5A) of the first dam pattern DAM-T is less than about 15 μm and the first dam pattern DAM-T does not completely block the traveling of the source light L1, the reflective pattern MSP may reflect the source light L1 traveling to the adjacent pixel areas PXA-R, PXA-G, and PXA-B and may prevent a color mixture between the pixel areas adjacent to each other.

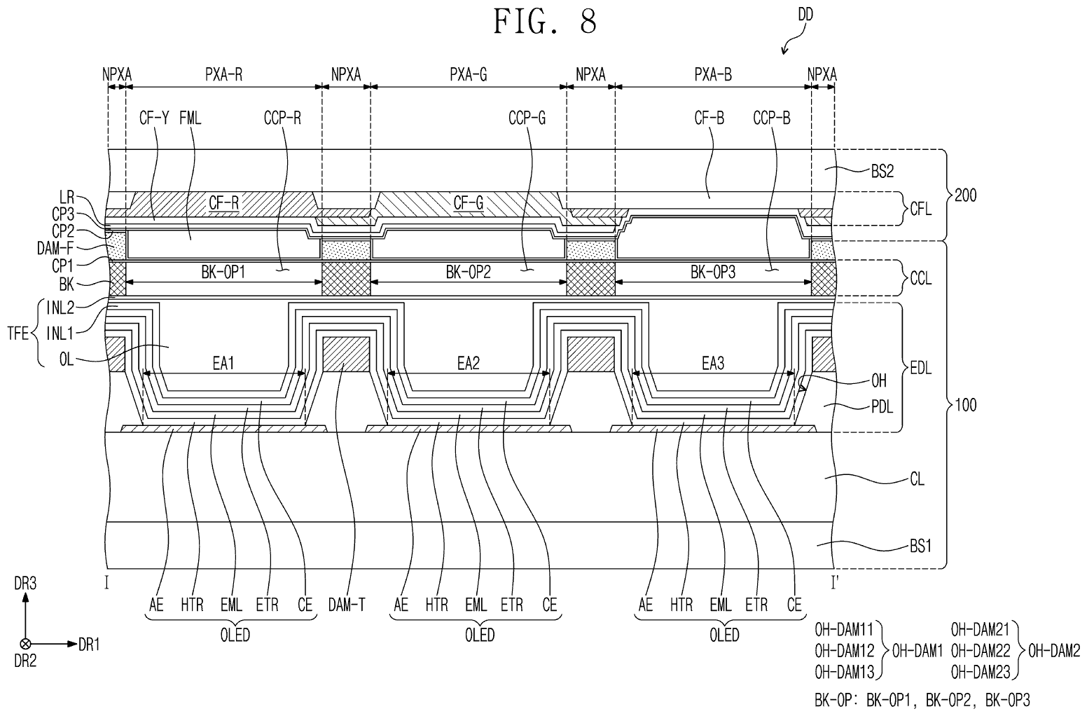

FIG. 8 is a schematic cross-sectional view taken along line I-I′ of FIG. 4 according to an embodiment. In FIG. 8, the same reference numerals denote the same elements in FIG. 5A, and thus, detailed descriptions of the same elements may be omitted.

Referring to FIG. 8, a second display substrate 200 may further include a block color filter CF-Y. The block color filter CF-Y may be disposed on a color filter layer CFL. The block color filter CF-Y may overlap a first pixel area PXA-R and a second pixel area PXA-G and may not overlap a third pixel area PXA-B. The block color filter CF-Y may be disposed on a first color filter CF-R and a second color filter CF-G. The block color filter CF-Y may not transmit the blue light (or the third color light) and may transmit the red light (or the first color light) and the green light (or the second color light).

The block color filter CF-Y may prevent the blue color, which is the color of the source light, from being displayed in the first pixel area PXA-R and second pixel area PXA-G where the red or green color is displayed. The block color filter CF-Y may prevent the blue light from traveling through the first pixel area PXA-R displaying the red light and the second pixel area PXA-G displaying the green light.

The block color filter CF-Y may have a transmittance (hereinafter, referred to as a first transmittance) of about 90% or more with respect to the red light (or the first color light) and the green light (or the second color light). In case that the first transmittance of the block color filter CF-Y is less than about 90%, not only the blue light (or the third color light) but also the red light displayed through the first pixel area PXA-R and the green light displayed through the second pixel area PXA-G may be blocked by the block color filter CF-Y. This may reduce luminance in the first pixel area PXA-R and the second pixel area PXA-G.

The block color filter CF-Y may have an extinction coefficient equal to or greater than about 0.005 and equal to or smaller than about 0.5 with respect to the blue light. In case that the extinction coefficient of the block color filter CF-Y with respect to the blue light increases, the block color filter CF-Y may absorb the blue light and may block the blue light from traveling outside. In case that the extinction coefficient of the block color filter CF-Y with respect to the blue light is smaller than about 0.005, the block color filter CF-Y may not absorb the blue light sufficiently and thus may not block the blue light. In case that the extinction coefficient of the block color filter CF-Y with respect to the blue light is greater than about 0.5, the block color filter CF-Y may absorb the blue light sufficiently to block the blue light, however, it is difficult to achieve the extinction coefficient of the block color filter CF-Y to be greater than about 0.5 considering the material used for the block color filter CF-Y.

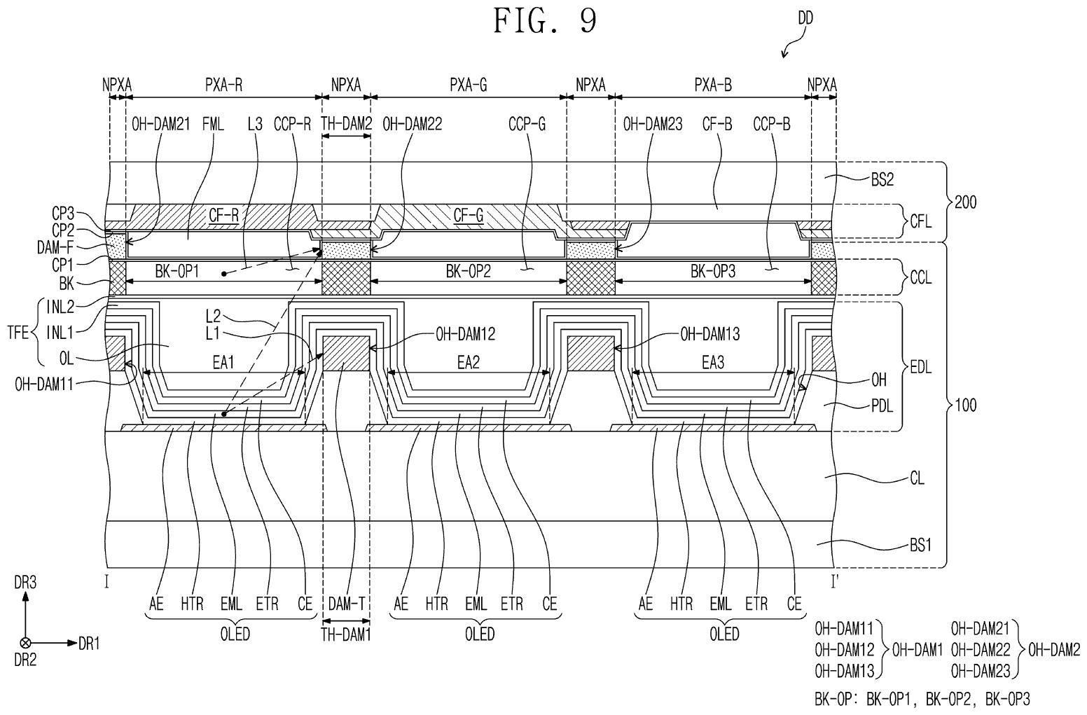

FIG. 9 is a schematic cross-sectional view taken along line I-I′ of FIG. 4 according to an embodiment. A display device DD of FIG. 9 may be substantially the same as the display device DD of FIG. 5A except that the display device DD of FIG. 9 does not include the low refractive index layer LR of FIG. 5A. In FIG. 9, the same reference numerals denote the same elements in FIG. 5A, and thus, detailed descriptions of the same elements may be omitted.

Referring to FIG. 9, a first capping layer CP1 may have a refractive index equal to or greater than about 1.0 and equal to or smaller than about 1.5. The refractive index of the first capping layer CP1 may be substantially the same as the refractive index of the low refractive index layer LR described with reference to FIG. 5A. Accordingly, the first capping layer CP1 may replace the function of the low refractive index layer LR (refer to FIG. 5A). For example, the first capping layer CP1 may be disposed between a light control layer CCL and a color filter layer CFL and may serve as an optical functional layer that improves a light extraction efficiency or prevents a reflected light from entering the light control layer CCL. The refractive index of the first capping layer CP1 may be smaller than a refractive index of a layer adjacent thereto.

A filling material FML may have a refractive index equal to or greater than about 1.0 and equal to or smaller than about 1.5. The refractive index of the filling material FML may be substantially the same as the refractive index of the low refractive index layer LR (refer to FIG. 5A) described with reference to FIG. 5A. Accordingly, the filling material FML may replace the function of the low refractive index layer LR (refer to FIG. 5A).

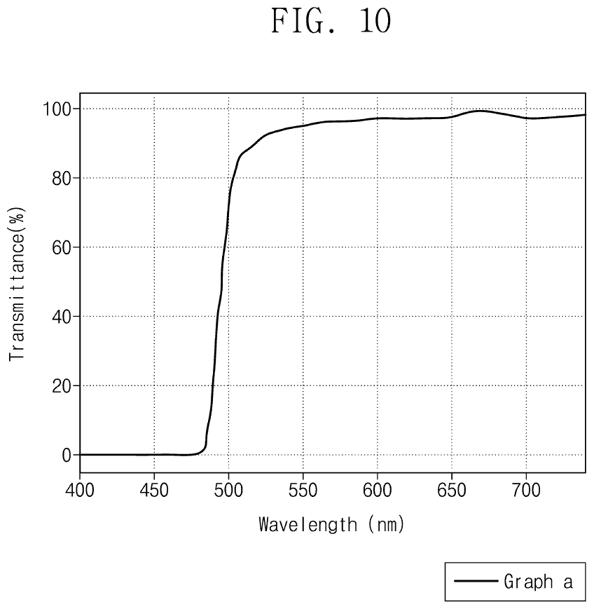

FIG. 10 is a graph illustrating a light transmittance of the block color filter as a function of a wavelength according to an embodiment.

Referring to FIG. 10, a graph a shows the light transmittance of the block color filter CF-Y as a function of the wavelength. The light transmittance of the block color filter CF-Y is about 0% in the blue light region with the wavelength of about 450 nm. The light transmittance of the block color filter CF-Y is about 94% in the green light region with the wavelength of about 540 nm. The light transmittance of the block color filter CF-Y is about 98% in the red light region with the wavelength of about 650 nm. As described above, the block color filter CF-Y may block only the blue light but may transmit the red light and the green light.

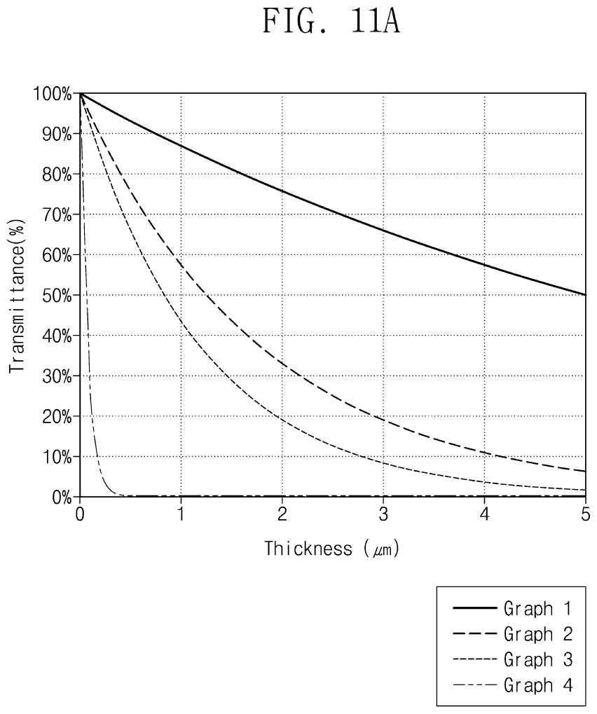

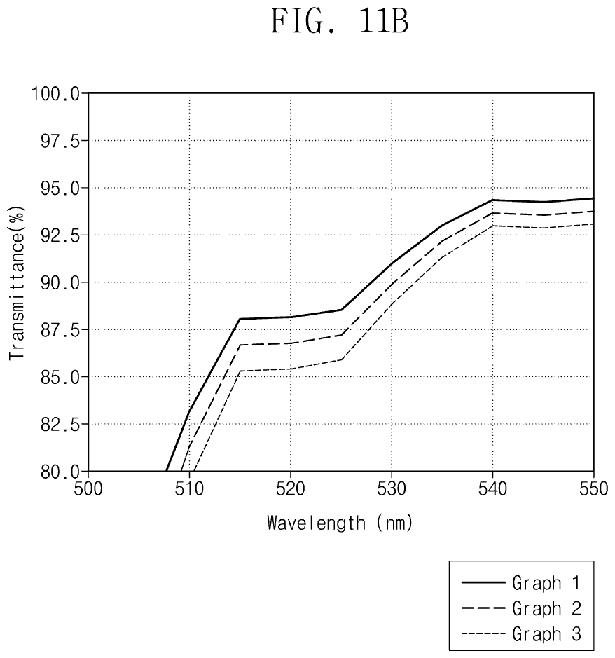

FIG. 11A is a graph illustrating a transmittance of the block color filter with respect to the blue light as a function of a thickness of the block color filter according to an embodiment. FIG. 11A is a graph showing the transmittance of the block color filter with respect to the blue light as a function of the thickness of the block color filter CF-Y measured in the first pixel area PXA-R.

In FIG. 11A, Graph 1 shows the transmittance as a function of the thickness of the block color filter CF-Y in case that the extinction coefficient of the block color filter CF-Y is about 0.005. Graph 2 shows the transmittance as a function of the thickness of the block color filter CF-Y in case that the extinction coefficient of the block color filter CF-Y is about 0.02. Graph 3 shows the transmittance as a function of the thickness of the block color filter CF-Y in case that the extinction coefficient of the block color filter CF-Y is about 0.03. Graph 4 shows the transmittance as a function of the thickness of the block color filter CF-Y in case that the extinction coefficient of the block color filter CF-Y is about 0.5.

Referring to FIG. 11A, it is observed that the transmittance of the block color filter CF-Y with respect to the blue light at the same thickness increases as the extinction coefficient of the block color filter CF-Y increases. In case that the extinction coefficient of the block color filter CF-Y is about 0.005 (graph 1), the transmittance of the block color filter CF-Y with respect to the blue light may be about 50%. In case that the extinction coefficient of the block color filter CF-Y is greater than about 0.005, the transmittance of the block color filter CF-Y with respect to the blue light may be greater than about 50%. As a result, the block color filter CF-Y may not block the blue light sufficiently.

In a case where the thickness of the block color filter CF-Y is not close to zero (0) and the extinction coefficient of the block color filter CF-Y is about 0.5 (graph 4), the transmittance of the block color filter CF-Y with respect to the blue light may be about 0%. Therefore, even though the extinction coefficient of the block color filter CF-Y is greater than about 0.5, it may not affect the blue light blocking effect of the block color filter CF-Y when compared to the case where the extinction coefficient is about 0.5. Thus, the extinction coefficient of the block color filter CF-Y may be equal to or greater than about 0.005 and equal to or smaller than about 0.5.

FIG. 11B is a graph illustrating a transmittance of the block color filter as a function of a wavelength in case that the thickness of the block color filter is varied according to an embodiment. FIG. 11B is a graph showing the transmittance of the block color filter CF-Y as a function of the wavelength of light measured in the second pixel area PXA-G.

In FIG. 11B, graph 1 shows the transmittance of the block color filter CF-Y as a function of the wavelength of light in case that the thickness of the block color filter CF-Y is about 4/m. Graph 2 shows the transmittance of the block color filter CF-Y as a function of the wavelength of light in case that the thickness of the block color filter CF-Y is about 4.5/m. Graph 3 shows the transmittance of the block color filter CF-Y as a function of the wavelength of light in case that the thickness of the block color filter CF-Y is about 5/m.

Referring to FIG. 11B, in case that a wavelength at a main peak of the green light (or the second color light) is about 530 nm, transmittances showed by graphs 1, 2, and 3 may be about 91%, about 90%, and about 89%, respectively. The transmittance of the block color filter CF-Y at the wavelength of about 530 nm is required to be about 90% or more to prevent the block color filter CF-Y from blocking not only the blue light but also the green light and thus to prevent the decrease in luminance. Accordingly, the thickness of the block color filter CF-Y may be smaller than about 4.5/m. However, in case that considering that the main peak of the green light varies depending on products and that the required transmittance for the green light varies depending on products, the thickness of the block color filter CF-Y may be changed as needed.

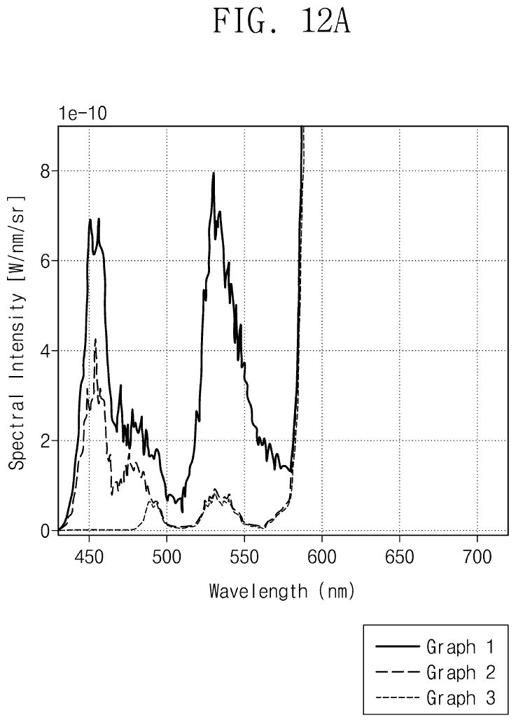

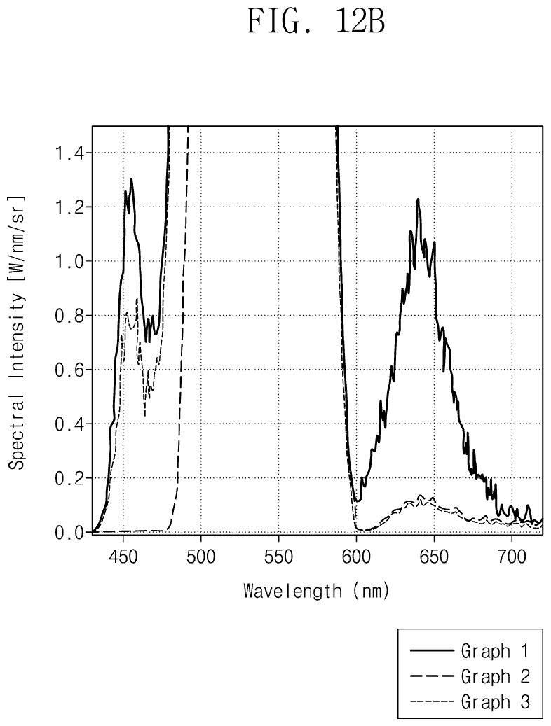

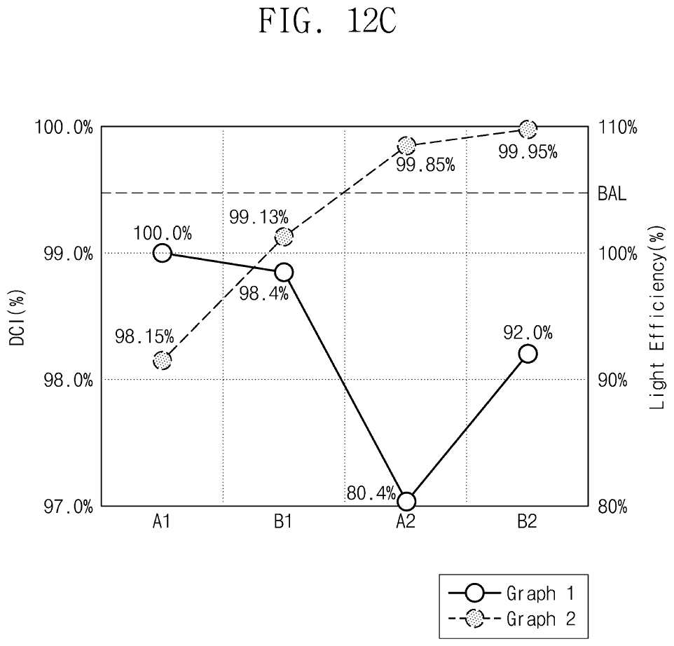

FIG. 12A is a graph illustrating a wavelength measured in a first pixel area as a function of a spectral intensity according to a comparative example and an embodiment example. FIG. 12B is a graph illustrating a wavelength measured in a second pixel area as a function of a spectral intensity according to a comparative example and an embodiment example.

In FIGS. 12A and 12B, graph 1 shows the spectral intensity as a function of the wavelength in the display device that does not include the first dam pattern DAM-T and the second dam pattern DAM-F according to the comparative example. Graph 2 shows the spectral intensity as a function of the wavelength in the display device DD that may include the first dam pattern DAM-T and the second dam pattern DAM-F of FIG. 5A according to embodiment example 1. Graph 3 shows the spectral intensity as a function of the wavelength in the display device DD that may include the first dam pattern DAM-T, the second dam pattern DAM-F, and the block color filter CF-Y of FIG. 8 according to embodiment example 2.

Referring to FIG. 12A, the first pixel area PXA-R may be the area from which the red light (or the first color light) is emitted. Hereinafter, the region where the wavelength is about 650 nm may be the red light region, the region where the wavelength is about 540 nm may be the green light region, and the region where the wavelength is about 450 nm may be the blue light region.

The peak value in the green light region and the blue light region of the comparative example (graph 1) may be greater than that of embodiment example 1 (graph 2). The peak value in the green light region and the blue light region of embodiment example 1 (graph 2) may be greater than that of embodiment example 2 (graph 3). This means that an amount of the green light and the blue light mixed with the red light is more in the comparative example (graph 1) than in embodiment example 1 (graph 2). This means that an amount of the green light and the blue light mixed with the red light is more in embodiment example 1 (graph 2) than in embodiment example 2 (graph 3).

Referring to FIG. 12B, the second pixel area PXA-G may be the area from which the green light (or the second color light) is emitted.

The peak value in the red light region and the blue light region of the comparative example (graph 1) may be greater than that of embodiment example 1 (graph 2). The peak value in the red light region and the blue light region of embodiment example 1 (graph 2) may be greater than that of embodiment example 2 (graph 3). This means that an amount of the red light and the blue light mixed with the green light is more in the comparative example (graph 1) than in embodiment example 1 (graph 2). This means that an amount of the red light and the blue light mixed with the green light is more in embodiment example 1 (graph 2) than in embodiment example 2 (graph 2).

Referring to FIGS. 12A and 12B, the first dam pattern DAM-T (refer to FIG. 5A) and the second dam pattern DAM-F (refer to FIG. 5A) of embodiment example 1 (graph 2) are effective in preventing the color mixture between the pixels adjacent to each other. The block color filter CF-Y (refer to FIG. 8) of embodiment example 2 (graph 3) is effective in preventing the color mixture between the pixels adjacent to each other.

FIG. 12C is a graph illustrating a light efficiency and a color gamut according to comparative examples and embodiment examples.

In FIG. 12C, A1 on a horizontal axis indicates the display device that does not include the first dam pattern DAM-T (refer to FIG. 5A) and the second dam pattern DAM-F (refer to FIG. 5A) according to comparative example 1. In FIG. 12C, B1 on the horizontal axis indicates the display device DD of FIG. 5A that may include the first dam pattern DAM-T (refer to FIG. 5A) and the second dam pattern DAM-F (refer to FIG. 5A) according to embodiment example 1. In FIG. 12C, A2 on the horizontal axis indicates a display device obtained by increasing a thickness of the color filter layer CFL of the display device DD of FIG. 5A according to comparative example 2. In FIG. 12C, B2 on the horizontal axis indicates the display device DD of FIG. 8 that may include the first dam pattern DAM-T, the second dam pattern DAM-F, and the block color filter CF-Y (refer to FIG. 8) according to embodiment example 2.

In FIG. 12C, graph 1 shows the light efficiency, and graph 2 shows the color gamut. The term “light efficiency” and “color gamut” used herein have the same meaning as described earlier.

When comparing comparative example 1 (A1) with embodiment example 1 (B1), the light efficiency decreases from about 100% to about 98.4% while the color gamut increases by about 1% from about 98.15% to about 99.13%. In case that comparing embodiment example 1 (B1) with comparative example 2 (A2), the light efficiency decreases by about 18% from about 98.4% to about 80.4%, and the color gamut increases by about 0.72% from about 99.13% to about 99.85%. When comparing comparative example 2 (A2) with embodiment example 2 (B2), the light efficiency increases from about 80.4% to about 92%, and the color gamut increases by about 0.1% from about 99.85% to about 99.95%.

In the display device according to comparative example 2 (A2) that is obtained by increasing the thickness of the color filter layer CFL (refer to FIG. 5A) of the display device DD of FIG. 5A, the color gamut slightly increases (about 0.72%), however, the light efficiency excessively decreases (about 18%). The decrease of the light efficiency described above causes a decrease in luminance of the display device DD.

In the display device according to embodiment example 2 (B2) that is obtained by adding the block color filter CF-Y (refer to FIG. 8) to the display device of embodiment example 1 (B1), the light efficiency decreases by about 6.4% from about 98.4% to about 92%, however, the color gamut increases by about 0.82% from about 99.13% to about 99.95%. When compared with comparative example 2 (A2), the decrease in light efficiency is relatively smaller and the increase in color gamut is relatively greater. Accordingly, it may be more appropriate to add the block color filter CF-Y as in embodiment example 2 (B2) rather than increasing the thickness of the color filter layer CFL as in comparative example 2 (A2) to increase the color gamut of the display device of embodiment example 1 (B1).

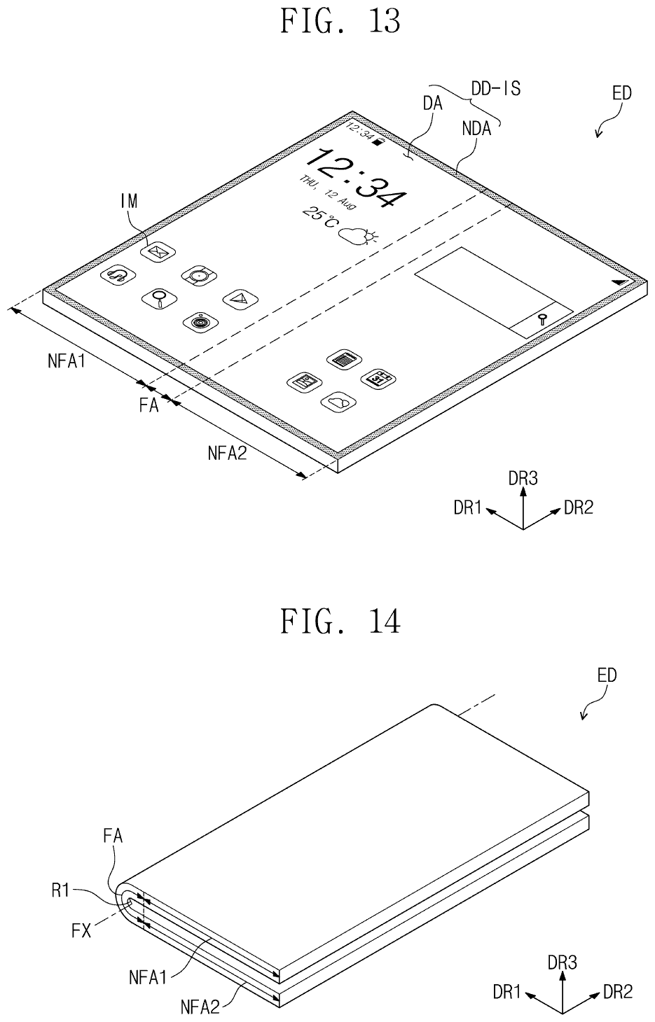

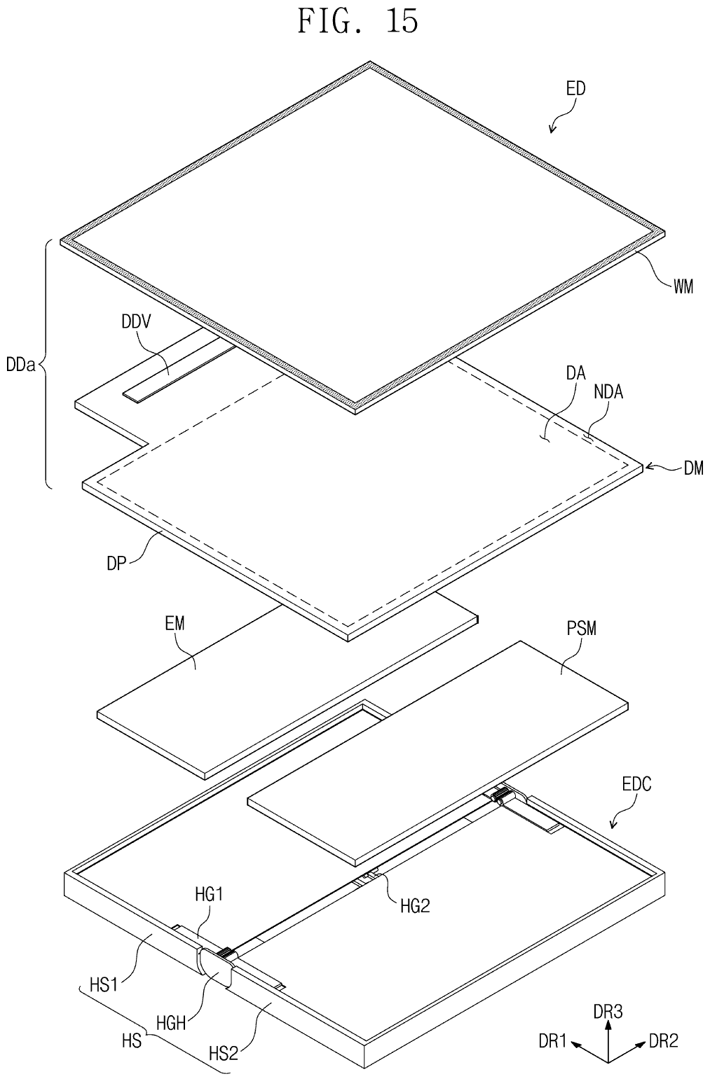

FIG. 13 is a perspective view of an electronic device according to an embodiment of the present disclosure. FIG. 14 is a view illustrating a folded state of the electronic device illustrated in FIG. 13.

Referring to FIG. 13, an electronic device ED according to an embodiment of the present disclosure may have a rectangular shape having short sides extending in a first direction DR1 and long sides extending in a second direction DR2 intersecting the first direction DR1. However, the present disclosure is not limited thereto, and the electronic device ED may have various shapes such as a circular shape and a polygonal shape. The electronic device ED may be flexible.

Hereinafter, a direction substantially perpendicular to a plane defined by the first direction DR1 and the second direction DR2 is defined as a third direction DR3. Further, in the specification, the wording “when viewed on a plane” may be defined as a state of being viewed from the third direction DR3.

The electronic device ED may include a folding area FA and a plurality of non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The folding area FA, the first non-folding area NFA1, and the second non-folding area NFA2 may be arranged in the first direction DR1.

Illustratively, one folding area FA and two non-folding areas NFA1 and NFA2 are illustrated, but the numbers of folding areas FA and the non-folding areas NFA1 and NFA2 are not limited thereto. For example, the electronic device ED may include more than two non-folding areas and a plurality of folding areas arranged between the non-folding areas.

An upper surface of the electronic device ED may be defined as a display surface DS, and the display surface DS may have the plane defined by the first direction DR1 and the second direction DR2. Images IM generated by the electronic device ED may be provided to a user through the display surface DS.

The display surface DS may include a display area DA and a non-display area NDA around the display area DA. The display area DA displays an image, and the non-display area NDA does not display the image. The non-display area NDA may surround the display area DA and may define an edge of the electronic device ED printed in a predetermined color.

Referring to FIG. 14, the electronic device ED may be a foldable electronic device ED that is folded or unfolded. For example, the folding area FA may be bent with respect to a folding axis FX parallel to the second direction DR2, and thus the electronic device ED may be folded. The folding axis FX may be defined as a long axis parallel to the long sides of the electronic device ED. When the electronic device ED is folded, the first non-folding area NFA1 and the second non-folding area NFA2 may face each other, and the electronic device ED may be in-folded so that the display surface DS is not exposed to the outside. However, an embodiment of the present disclosure is not limited thereto. For example, although not illustrated, the electronic device ED may be out-folded so that the display surface DS is exposed to the outside about the folding axis FX. Further, although not illustrated, the electronic device ED may be in-folded and out-folded at the same time.

FIG. 15 is an exploded perspective view of the electronic device illustrated in FIG. 13.

Referring to FIG. 15, the electronic device ED may include a display device DD, an electronic module EM, a power supply module PSM, and a hinge module EDC. Although not illustrated, the electronic device ED may further include a mechanical structure (e.g., a hinge) for controlling a folding operation of the display device DD. The hinge will be described in detail below.

The display device DDa may generate an image and sense an external input. The display device DDa may include a window module WM and a display module DM. The window module WM may provide a front surface of the electronic device ED. The window module WM may be disposed on the display module DM to protect the display module DM. The window module WM may transmit a light generated by the display module DM and provide the light to the user.

The display module DM may include a display panel DP. FIG. 15 illustrates only the display panel DP among laminated structures of the display module DM, but substantially, the display module DM may further include a plurality of components arranged on an upper side and a lower side of the display panel DP. The display panel DP may include a display area DA and a non-display area NDA corresponding to the display area DA and the non-display area NDA of FIG. 13 of the electronic device ED.

The display module DM may include a data driver DDV disposed on the non-display area NDA of the display panel DP. The data driver DDV may be directly manufactured in the form of a circuit chip and mounted on the non-display area NDA. However, the present disclosure is not limited thereto, and the data driver DDV may be mounted on a flexible circuit board connected to the display panel DP.

The electronic module EM and the power supply module PSM may be arranged inside the hinge module EDC. Illustratively, FIG. 15 illustrates a state in which the electronic module EM and the power supply module PSM are exposed to the outside from the hinge module EDC. Although not illustrated, the electronic module EM and the power supply module PSM may be connected to each other through a separate flexible circuit board. The electronic module EM may control an operation of the display device DD. The power supply module PSM may supply power to the electronic module EM.

The hinge module EDC may accommodate the display device DD, the electronic module EM, and the power supply module PSM. The hinge module EDC may include two first and second housings HS1 and HS2 for folding the display device DD. The first and second housings HS1 and HS2 may extend in the second direction DR2 and may be arranged in the first direction DR1.

The hinge module EDC may include a housing assembly HS. The housing assembly HS may include the first housing HS1 and the second housing HS2 spaced apart from each other in the first direction DR1 and a hinge housing HGH disposed between the first housing HS1 and the second housing HS2. The hinge module EDC may further include hinges HG1 and HG2 for connecting the first and second housings HS1 and HS2, a plurality of main plates, and a plurality of moving plates.

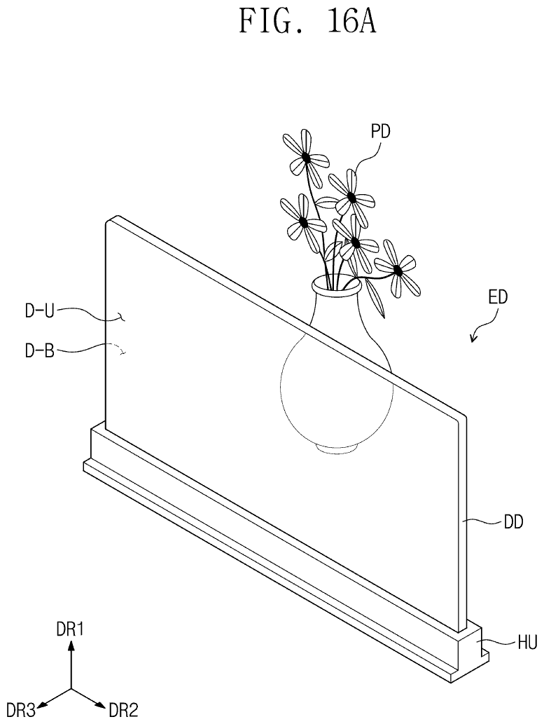

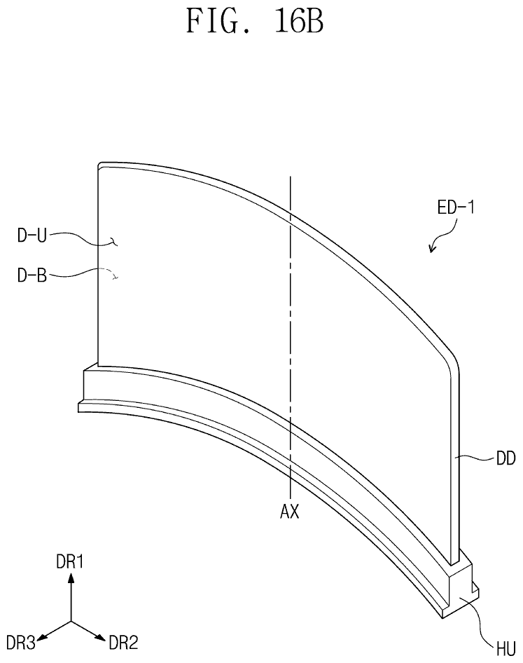

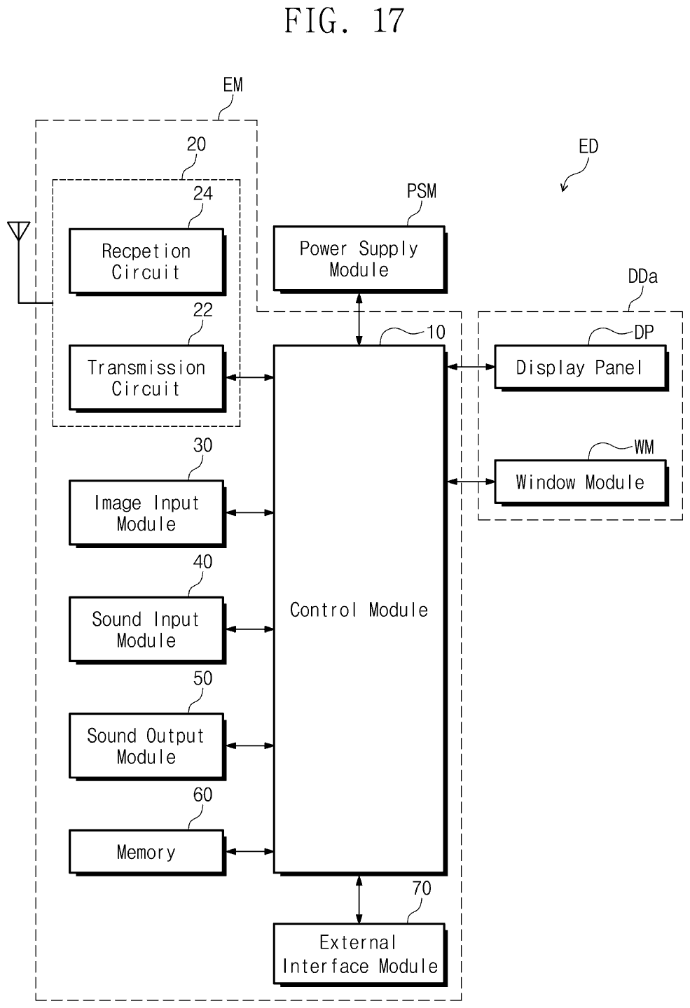

FIG. 16A is a perspective view of an electronic device according to according to an embodiment of the present disclosure. FIG. 16B is a perspective view of a curved electronic device according to an embodiment of the present disclosure.

Each of electronic devices ED and ED-1 illustrated in FIGS. 16A and 16B may include a display device DD and a housing HU that accommodates at least a portion of the display device DD. For example, a portion of a lower end of the display device DD may be accommodated in the housing HU.

Referring to FIG. 16A, the display device DD may display an image through a front surface D-U. A top surface of a member disposed at the uppermost side of the display device DD may be defined as the front surface D-U of the display device DD. According to the inventive concept, a top surface of a window WD illustrated in FIG. 2 may be defined as the front surface D-U of the display device DD.

Referring to FIG. 16B, the electronic device ED-1 according to an embodiment may be curved along the second direction DR2 based on a virtual axis AX extending in the first direction DR1. Thus, the display device DD may be curved at a predetermined curvature, and the housing HU may have a corresponding curvature. It is not limited thereto, and the axis may extend in the second direction DR2 or be curved based on a plurality of axes extending in different directions.

The display device DD according to the inventive concept may be a transparent display device DD. The transparent display device DD may display information in a state in which an object PD disposed on a rear surface D-B of the display device DD is transparently reflected on the front side D-U of the display device DD. Thus, a user may recognize the object disposed on the rear surface D-B of the display device DD from the front surface D-U of the display device DD. The information is not limited to any one of images, content, playback screens, application execution screens, web browser screens, and various graphic objects. In FIG. 16B, a vase is shown as an example of the object PD, but the object PD is not limited thereto. The object PD may have a specific shape and is not limited to any one object.

FIG. 17 is a block diagram of the electronic device illustrated in FIG. 15.

Referring to FIG. 17, the electronic device ED may include the electronic module EM, the power supply module PSM, and the display device DD. The electronic module EM may include a control module 10, a wireless communication module 20, an image input module 30, a sound input module 40, a sound output module 50, a memory 60, an external interface module 70, and the like. The modules may be mounted on a circuit board or may be electrically connected through a flexible circuit board. The electronic module EM may be electrically connected to the power supply module PSM.

The control module 10 may control an overall operation of the electronic device ED. For example, the control module 10 may activate or deactivate the display device DDa in accordance with a user input. The control module 10 may control the image input module 30, the sound input module 40, the sound output module 50, and the like in accordance with the user input. The control module 10 may include at least one microprocessor.

The wireless communication module 20 may transmit/receive a wireless signal to/from another terminal using a Bluetooth line or a Wi-Fi line. The wireless communication module 20 may transmit/receive a voice signal using a general communication line. The wireless communication module 20 may include a transmission circuit 22 for modulating and transmitting a signal to be transmitted, and a reception circuit 24 for demodulating a received signal.

The image input module 30 may process an image signal and convert the image signal into image data that may be displayed on the display device DD. The sound input module 40 may receive an external sound signal through a microphone in a recording mode or a voice recognition mode and convert the received external sound signal into electrical voice data. The sound output module 50 may convert sound data received from the wireless communication module 20 or sound data stored in the memory 60 and output the converted sound data to the outside.

The external interface module 70 may serve as an interface connected to an external charger, a wired/wireless data port, and a card socket (e.g., a memory card, a subscriber identity module (SIM)/user interface model (UIM) card).

The power supply module PSM may supply power required for an overall operation of the electronic device ED. The power supply module PSM may include a general battery device.

Although embodiments have been described, it will be understood that the disclosure should not be limited to these embodiments but various changes and modifications can be made by one of ordinary skill in the art within the spirit and scope of the disclosure and as hereinafter claimed. Therefore, the disclosed subject matter should not be limited to any single embodiment described herein, and the scope of the disclosure shall be determined according to the attached claims.

What is claimed is:

1. A display device comprising:
a base layer comprising a pixel area and a peripheral area surrounding the pixel area;
a pixel definition layer disposed on the base layer, the pixel definition layer including a light emitting opening in the pixel definition layer;
a light emitting element overlapping the pixel area and generating a source light;
an encapsulation layer comprising a first inorganic layer covering the light emitting element, an organic layer disposed on the first inorganic layer, and a second inorganic layer disposed on the organic layer;
a first dam pattern disposed on the pixel definition layer, the first dam pattern including a first dam opening in the first dam pattern, the first dam opening overlapping the peripheral area;
a bank disposed on the encapsulation layer, the bank including an opening in the bank;
a light control pattern disposed in the opening and converting the source light to an output light;
a second dam pattern disposed on the bank, the second dam pattern including a second dam opening in the second dam pattern; and
a color filter overlapping the pixel area, wherein
the organic layer is disposed in the first dam opening, and the second dam opening is filled with a filling material.

2. The display device of claim 1, wherein
a transmittance of the first dam pattern with respect to the source light is lower than a transmittance of the encapsulation layer with respect to the source light, and
a transmittance of the second dam pattern with respect to the source light is lower than a transmittance of the filling material with respect to the source light.

3. The display device of claim 1, wherein a transmittance of the second dam pattern with respect to the output light is lower than a transmittance of the filling material with respect to the output light.

4. The display device of claim 3, further comprising a first capping layer that covers the bank and the light control pattern.

5. The display device of claim 4, wherein the first capping layer contacts the light control pattern and has a refractive index equal to or greater than about 1.0 and equal to or less than about 1.5.

6. The display device of claim 1, wherein the first dam pattern is disposed on the pixel definition layer and above the light emitting element.

7. The display device of claim 1, wherein the first dam pattern is disposed between the first inorganic layer and the organic layer.

8. The display device of claim 1, wherein
the first dam pattern is disposed between the first inorganic layer and the second inorganic layer, and
an upper surface of the first dam pattern contacts the second inorganic layer.

9. The display device of claim 1, wherein the filling material has a refractive index equal to or greater than about 1.0 and equal to or less than about 1.5.

10. The display device of claim 1, further comprising a low refractive index layer disposed between the color filter and the filling material.

11. The display device of claim 1, further comprising a reflective pattern disposed on an inner side surface of the first dam pattern.

12. The display device of claim 1, further comprising:
a block color filter disposed on the color filter, wherein
the pixel area comprises a first pixel area, a second pixel area, and a third pixel area, the color filter comprises a first color filter overlapping the first pixel area and transmitting a first color light, a second color filter overlapping the second pixel area and transmitting a second color light, and a third color filter overlapping the third pixel area and transmitting a third color light, and
the block color filter overlaps the first pixel area and the second pixel area and does not overlap the third pixel area.

13. The display device of claim 12, wherein the block color filter has an extinction coefficient equal to or greater than about 0.005 and equal to or less than about 0.5 with respect to the third color light.

14. The display device of claim 12, wherein the block color filter has a transmittance equal to or greater than about 90% with respect to each of the first color light and the second color light.

15. The display device of claim 12, wherein
one of the first color light and the second color light is a red light or a green light, and
the third color light is a blue light.

16. A display device comprising:
a base layer comprising a first pixel area, a second pixel area, and a third pixel area and a peripheral area surrounding the first pixel area, the second pixel area, and the third pixel area;
a pixel definition layer disposed on the base layer and including light emitting openings, the pixel definition layer overlapping a peripheral area, respectively;
a light emitting element overlapping the first pixel area, the second pixel area, and the third pixel area and generating a source light;
an encapsulation layer comprising a first inorganic layer covering the light emitting element, an organic layer disposed on the first inorganic layer, and a second inorganic layer disposed on the organic layer;
a first dam pattern disposed on the pixel definition layer, the first dam pattern including (1-1)th, (1-2)th, and (1-3)th dam openings included in the first dam pattern, the (1-1)th, (1-2)th, and (1-3th) dam openings overlapping the peripheral area;
a bank disposed on the first dam pattern, the bank including first openings, second openings, and third openings in the bank;
a first light control pattern, a second light control pattern, and a third light control pattern disposed in the first openings, the second openings, and the third openings, respectively, and converting an optical property of the source light; and
a second dam pattern disposed on the bank, the second dam pattern including (2-1)th, (2-2)th, and (2-3)th dam openings in the second dam pattern, wherein the organic layer is disposed in the (1-1)th, (1-2)th, and (1-3)th dam openings, and the (2-1)th, (2-2)th, and (2-3)th dam openings are filled with a filling material.

17. The display device of claim 16, further comprising a first color filter, a second color filter, and a third color filter disposed on the filling material, wherein
the first color filter overlaps the first pixel area and transmits a first color light,
the second color filter overlaps the second pixel area and transmits a second color light, and
the third color filter overlaps the third pixel area and transmits a third color light.

18. The display device of claim 17, further comprising a block color filter disposed on the first color filter and the second color filter, wherein
the block color filter overlaps the first pixel area and the second pixel area and does not overlap the third pixel area.

19. The display device of claim 18, wherein the block color filter has an extinction coefficient equal to or greater than about 0.005 and equal to or less than about 0.5 with respect to the third color light.

20. The display device of claim 18, wherein the block color filter has a transmittance equal to or greater than about 90% with respect to each of the first color light and the second color light.

21. An electronic device activated in response to electrical signals, comprising:
a display device curved with respect to a virtual axis extending in a first direction;
an electronic module overlapping the display device; and
a housing accommodating the display device,
wherein the display device comprising:
a base layer comprising a pixel area and a peripheral area surrounding the pixel area;
a pixel definition layer disposed on the base layer, the pixel definition layer including a light emitting opening in the pixel definition layer;
a light emitting element overlapping the pixel area and generating a source light;
an encapsulation layer comprising a first inorganic layer covering the light emitting element, an organic layer disposed on the first inorganic layer, and a second inorganic layer disposed on the organic layer;
a first dam pattern disposed on the pixel definition layer, the first dam pattern including a first dam opening in the first dam pattern, the first dam opening overlapping the peripheral area;
a bank disposed on the encapsulation layer, the bank including an opening in the bank;
a light control pattern disposed in the opening and converting the source light to an output light;
a second dam pattern disposed on the bank, the second dam pattern including a second dam opening in the second dam pattern; and
a color filter overlapping the pixel area, wherein
the organic layer is disposed in the first dam opening, and the second dam opening is filled with a filling material.

22. The electronic device of claim 21, wherein the electronic device is television set, computer monitor, outdoor billboard, mobile phone, tablet computer, navigation unit, game unit or smart watch.

23. The electronic device of claim 21, wherein the electronic module includes a control module, an image input module and a memory.
